(19) United States
(12) Patent Application Publication
(10) Pub. No.: US 2025/0329516 A1
(43) Pub. Date: Oct. 23, 2025

(54) ETCHING METHOD

(71) Applicant: Resonac Corporation, Tokyo (JP)

(72) Inventors: Kazuma MATSUI, Tokyo (JP); Yuki OKA, Tokyo (JP); Moe TANIWAKI, Tokyo (JP)

(73) Assignee: Resonac Corporation, Tokyo (JP)

(21) Appl. No.: 18/868,552

(22) PCT Filed: May 30, 2023
(86) PCT No.: PCT/JP2023/020126

§ 371 Date: Nov. 22, 2024

(30) Foreign Application Priority Data
May 31, 2022 (JP) 2022-089058

(51) Int. Cl. H01J 37/32; H01L 21/311

(52) U.S. Cl. CPC H01J 37/32449; H01L 21/31116; H01J 2237/334

(57) ABSTRACT

An etching method includes: an etching step of bringing an etching gas containing an etching compound into contact with a member to be etched (400) having an etching object (carbon material) subject to etching by the etching gas, plasm etching the etching object, and forming a hole in the etching object. The etching compound is fluoro-dithiethane represented by Chemical Formula CₓF_{y}S₂, wherein, in Chemical Formula, x is 2 or more and 6 or less and y is 4 or more and 12 or less. The etching gas contains or does not contain at least one type among sodium, magnesium, aluminum, potassium, calcium, chromium, manganese, iron, cobalt, nickel, copper, and molybdenum, and, when the at least one type of metal is contained, the total concentration of all types of the metals contained is 100 ppb by mass or less.

### TECHNICAL FIELD

The present invention relates to an etching method.

### BACKGROUND ART

The most advanced dry etching process has been required to have excellent etching characteristics, such as an etching selectivity, an etching rate, and vertical processability. The development of a novel etching gas satisfying the requirements has been desired.

PTLS 1, 2 disclose dry etching methods for etching carbon materials, such as amorphous carbon, using an etching gas containing a sulfur-containing compound as an etching compound. When a hole (e.g., through hole) is formed in a carbon material by the dry etching methods disclosed in PTLS 1, 2, a polymer resistant to etching is generated from the etching compound, and a protective film containing the polymer is formed on the side wall surface of the hole. This suppresses etching of the side wall surface of the hole, and therefore bowing hardly occurs. More specifically, a phenomenon hardly occurs in which the side wall surface becomes a barrel shape instead of a cylindrical shape by etching in the radial direction of the hole (direction orthogonal to the depth direction of the hole) of the side wall surface of an intermediate part in the depth direction (etching direction) of the hole.

### CITATION LIST

### Patent Literatures

PTL 1: JP 6676724 B
PTL 2: JP 2021-106212 A

### SUMMARY OF INVENTION

### Technical Problem

With the miniaturization of semiconductor devices and the development of three-dimensional semiconductor devices, the dry etching process has been required to be further improved in the etching characteristics described above, particularly vertical processability. More specifically, a dry etching process has been required in which the bowing hardly occurs in the side wall surface of a hole when the hole is formed by etching.

It is an object of the present invention to provide an etching method in which the bowing hardly occurs in the side wall surface of a hole in the formation of the hole by etching.

### Solution to Problem

To achieve the above-described object, one aspect of the present invention is as described in [1] to [7] below.

[1] An etching method includes: an etching step of bringing an etching gas containing an etching compound into contact with a member to be etched having an etching object subject to etching by the etching gas, plasm etching the etching object, and forming a hole in the etching object, in which
the etching object has a carbon material,
the etching compound is fluoro-dithiethane represented by Chemical Formula CₓF_{y}S₂, wherein, in Chemical Formula above, x is 2 or more and 6 or less and y is 4 or more and 12 or less, and
the etching gas contains or does not contain at least one type of metal among sodium, magnesium, aluminum, potassium, calcium, chromium, manganese, iron, cobalt, nickel, copper, and molybdenum, and, when the at least one type of metal is contained, the total concentration of all types of the contained metals is 100 ppb by mass or less.

[2] The etching method according to [1], in which the fluoro-dithiethane has at least one type among 2,2,4,4-tetrafluoro-1,3-dithietane, 1,1,2,2,3,3,4,4-octafluoro-1,3-dithietane, 2,2,4-trifluoro-4-trifluoromethyl-1,3-dithietane, 2,4-difluoro-2,4-bis(trifluoromethyl)-1,3-dithietane, and 2,2,4,4-tetrakis(trifluoromethyl)-1,3-dithietane.

[3] The etching method according to [1] or [2], in which the carbon material has at least one of amorphous carbon and carbon-doped silicon oxide.

[4] The etching method according to any one of [1] to [3], in which the etching gas contains the fluoro-dithiethane and at least one of a second etching compound and an inert gas.

[5] The etching method according to [4], in which the second etching compound is at least one type among oxygen gas, nitrogen gas, and fluorocarbon.

[6] The etching method according to any one of [1] to [5], in which a temperature condition of the etching step is 0° C. or more and 40° C. or less.

[7] The etching method according to any one of [1] to [6], in which a pressure condition of the etching step is 1 Pa or more and 5 Pa or less.

### Advantageous Effects of Invention

According to the present invention, the bowing hardly occurs in the side wall surface of a hole in the formation of the hole by etching.

### BRIEF DESCRIPTION OF DRAWINGS

FIG. 1 is a schematic view illustrating one example of an etching device for explaining one embodiment of an etching method according to the present invention;

FIG. 2 is a schematic view illustrating one example of a purification device purifying fluoro-dithiethane;

FIG. 3 is a schematic view illustrating one example of a preparation device preparing an aqueous nitric acid solution to be used for measuring the concentration of metal in fluoro-dithiethane;

FIG. 4 is a cross-sectional view illustrating one example of a member to be etched before etching;

FIG. 5 is a plan view illustrating the shape of an opening part of an anti-reflective film layer formed on the member to be etched after etching;

FIG. 6 is a cross-sectional view illustrating the shape of a hole formed in the member to be etched after etching;

FIG. 7 is a plan view illustrating the shapes of opening parts of the anti-reflective film layer formed on the member to be etched after etching; and

FIG. 8 is a cross-sectional view illustrating the shape of the hole formed in the member to be etched after etching.

### DESCRIPTION OF EMBODIMENTS

Hereinafter, one embodiment of the present invention is described. This embodiment describes one example of the present invention, and the present invention is not limited to this embodiment. This embodiment can be variously altered or improved, and such altered or improved aspects can also be included in the present invention.

An etching method according to this embodiment includes an etching step of bringing an etching gas containing an etching compound into contact with a member to be etched having an etching object subject to etching by the etching gas, plasm etching the etching object, and forming a hole in the etching object.

The etching object has a carbon material. The etching compound is fluoro-dithiethane represented by Chemical Formula CₓF_{y}S₂. In Chemical Formula above, x is 2 or more and 6 or less and y is 4 or more and 12 or less.

The etching gas contains or does not contain at least one type of metal among sodium (Na), magnesium (Mg), aluminum (Al), potassium (K), calcium (Ca), chromium (Cr), manganese (Mn), iron (Fe), cobalt (Co), nickel (Ni), copper (Cu), and molybdenum (Mo), and, when the at least one type of metal is contained, the total concentration of all types of the contained metals is 100 ppb by mass or less.

When the etching gas containing an etching compound is brought into contact with the member to be etched, the carbon material, which is the etching object, and the etching compound in the etching gas react with each other, and therefore the etching of the carbon material progresses. Thus, the etching method according to this embodiment is capable of forming a hole in the etching object by plasma etching.

Further, according to the etching method of this embodiment, the etching is performed using the etching gas not containing the metals or containing the metals in an extremely small amount, even when the etching gas contains the metals as described above, and therefore can suppress the occurrence of bowing in the side wall surface of the hole.

Thus, the etching method according to this embodiment can be utilized for the manufacture of semiconductor elements. For example, when the etching method according to this embodiment is applied to a semiconductor substrate having a thin film containing a carbon material, and plasma etching for forming a hole in the thin film containing a carbon material is performed, a three-dimensionally integrated semiconductor element can be manufactured.

The hole in the present invention is a hole opened in the surface of the etching object and extending in a direction orthogonal to the surface of the etching object. The hole may be a through hole penetrating the etching object or may be a bottomed hole not penetrating the etching object. The planar shape (shape of the opening) of the hole includes a circular shape, an oval shape, a polygonal shape (e.g., rectangular shape), a closed free curved shape, a linear shape (e.g., slit shape), and the like.

The etching in the present invention means removing a part of the etching object possessed by the member to be etched to form a hole, and may further include removing a part of the etching object possessed by the member to be etched to process the member to be etched into a predetermined shape (e.g., three-dimensional shape) (e.g., processing a film-like etching object containing a carbon material possessed by the member to be etched to have a predetermined film thickness).

The “metal” in the “metal concentration” in the present invention includes metal atoms and metal ions.

Hereinafter, the etching method according to this embodiment is described in more detail.

### [Etching Method]

For the etching method according to this embodiment, plasma etching using plasma is used. The plasma etching includes reactive ion etching (RIE), inductively coupled plasma (ICP) etching, capacitively coupled plasma (CCP) etching, electron cyclotron resonance (ECR) plasma etching, and microwave plasma etching, for example.

In the plasma etching, plasma may be generated in a chamber where the member to be etched is placed or a plasma generating chamber and the chamber where the member to be etched is placed may be separated from each other (i.e., remote plasma may be used).

### [Etching Compound]

The etching compound contained in the etching gas is a compound that advances the etching of the carbon material in an environment in which the etching gas is converted into plasma. The etching compound is the fluoro-dithiethane represented by Chemical Formula CₓF_{y}S₂, wherein, in Chemical Formula above, x is 2 or more and 6 or less and y is 4 or more and 12 or less. However, from the viewpoint of ease of accessibility and ease of handling, fluoro-dithiethane, wherein, in Chemical Formula above, x is 2 or more and 4 or less and y is 4 or more and 12 or less, is preferable. The etching compounds may be used alone or in combination of two or more types thereof.

The fluoro-dithiethane represented by Chemical Formula CₓF_{y}S₂ includes fluoro-dithiethane having a 1,2-dithietane structure and fluoro-dithiethane having a 1,3-dithietane structure, both of which are usable as the etching compound in the etching method according to this embodiment. From the viewpoint of ease of accessibility, the fluoro-dithiethane having a 1,3-dithietane structure is preferable and fluoro-dithiethane having a 1,3-dithietane structure and having no unsaturated bonds is more preferable.

When the etching is performed using an etching gas containing the above-described fluoro-dithiethane, a film of a compound having a carbon-sulfur bond is formed on the surface of the carbon material. The compound film has relatively high resistance to activated species effective for the etching of the carbon material. Therefore, this compound film has an action of suppressing the etching of the carbon material.

In the etching step of forming a hole in the etching object, the above-described compound film is formed on the side wall surface of the hole. As a result, the etching of the side wall surface of the hole is suppressed, and therefore the bowing hardly occurs in the side wall surface of the hole when the hole is formed.

The fluoro-dithiethane has a fluorine atom in the molecule, and therefore the etching gas containing the fluoro-dithiethane is excellent in the action of etching the carbon material in the vertical direction. More specifically, the etching gas containing the fluoro-dithiethane is excellent in performance of forming the hole, which extends in the direction orthogonal to the surface of the etching object, in the etching object.

Examples of the fluoro-dithiethane having a 1,3-dithietane structure and having no unsaturated bonds include 2,2,4,4-tetrafluoro-1,3-dithietane (C₂F₄S₂, see Chem. 1), 1,1,2,2,3,3,4,4-octafluoro-1,3-dithietane (C₂F₄S₂, see Chem. 2), 1,1,2,2,4,4-hexafluoro-1,3-dithietane (C₂F₆S₂, see Chem. 3), 1,1,1,1,2,2,3,3,3,3,4,4-dodecafluoro-1,3-dithietane (C₂F₁₂S₂, see Chem. 4), 2,2,4-trifluoro-4-trifluoromethyl-1,3-dithietane (C₃F₆S₂, see Chem. 5), 2,4-difluoro-2,4-bis(trifluoromethyl)-1,3-dithietane (C₄F₈S₂, see Chem. 6), and 2,2,4,4-tetrakis(trifluoromethyl)-1,3-dithietane (C₆F₁₂S₂, see Chem. 7).

Among the fluoro-dithiethanes above, the fluoro-dithiethanes are more preferably 2,2,4,4-tetrafluoro-1,3-dithietane, 1,1,2,2,3,3,4,4-octafluoro-1,3-dithietane, 2,2,4-trifluoro-4-trifluoromethyl-1,3-dithietane, 2,4-difluoro-2,4-bis(trifluoromethyl)-1,3-dithietane, and 2,2,4,4-tetrakis(trifluoromethyl)-1,3-dithietane, and 2,2,4,4-tetrafluoro-1,3-dithietane is still more preferable due to relatively ease of vaporization.

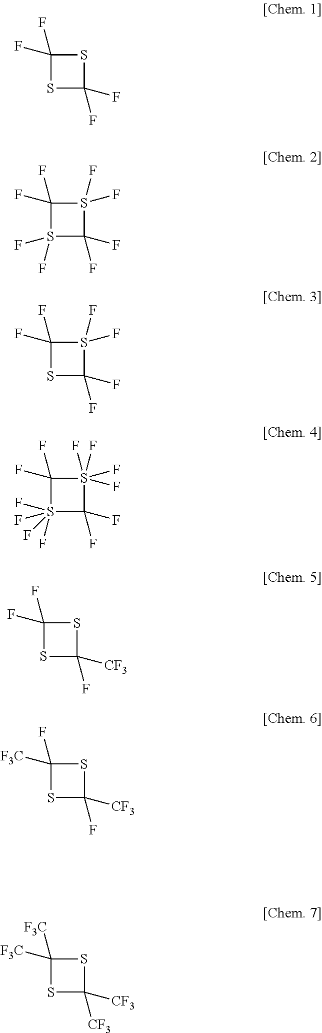

### [Etching Gas]

The etching gas is a gas containing the etching compound (fluoro-dithiethane), and may be a gas containing only the etching compound or may be a mixed gas containing the etching compound and the other type of gas other than the etching compound.

When the etching gas is the mixed gas containing the etching compound and the other type of gas, the concentration of the etching compound contained in the etching gas is not particularly limited insofar as it is the concentration at which the carbon material can be processed and can be set to more than 0% by volume and less than 100% by volume, for example.

The concentration of the etching compound contained in the etching gas may be adjusted according to the type of an etching process in the etching method according to this embodiment. For example, the concentration of the etching compound contained in the etching gas may be changed as appropriate depending on whether the etching process in the etching method according to this embodiment is a non-alternating process or an alternating process.

Herein, the non-alternating process is an etching process of simultaneously carrying out the etching of the carbon material that increases the depth of the hole and the formation of a protective film containing a polymer generated from the fluoro-dithiethane in the side wall surface of the hole and continuously generating plasma from the start of the etching to the completion of the etching.

The alternating process is an etching process of alternately repeating a process of performing etching that increases the depth of the hole (hereinafter referred to as “deep etching process”) and a process of mainly depositing a protective film containing a polymer generated from the fluoro-dithiethane on the side wall surface of the hole (hereinafter referred to as “sidewall protection process”). The etching that increases the depth of the hole progresses also in the sidewall protection process, although the degree of increase in the depth of the hole is smaller than that in the deep etching process. In the alternating process, the generation of plasma is stopped when the process is switched between the deep etching process and the sidewall protection process.

In the case of the non-alternating process, the concentration of the etching compound contained in the etching gas may be relatively low to suppress excessive deposition of the protective film on the side wall surface of the hole, and is preferably 0.1% by volume or more and 40% by volume or less, more preferably 0.5% by volume or more and 20% by volume or less, and still more preferably 1% by volume or more and 10% by volume or less, for example.

In the case of the alternating process, an etching gas used in the deep etching process and an etching gas used in the sidewall protection process may have the same etching compound concentration or may have different etching compound concentrations. However, the concentration of the etching compound is preferably lower in the etching gas used in the deep etching process than in the etching gas used in the sidewall protection process.

In the deep etching process, the etching gas does not have to contain the etching compound to increase the etching rate of the carbon material, or the concentration of the etching compound in the etching gas may be low, and is preferably more than 0% by volume and 10% by volume or less and more preferably more than 0% by volume and 5% by volume or less, for example.

In the sidewall protection process, the concentration of the etching compound in the etching gas may be relatively high to facilitate the formation of the protective film, and is preferably 20% by volume or more and 100% by volume or less and more preferably 35% by volume or more and 90% by volume or less, for example.

When the concentration of the etching compound in the etching gas is in the numerical ranges above and, when the etching gas does not contain the metals or the total concentration of all types of the contained metals is 100 ppb by mass or less, a hole having a good shape is likely to be formed. More specifically, the etching of the side wall surface of the hole is suppressed, and therefore the bowing hardly occurs in the side wall surface of the hole when the hole is formed and the side wall surface of an intermediate part in the depth direction (etching direction) of the hole is likely to have a cylindrical shape instead of a barrel shape.

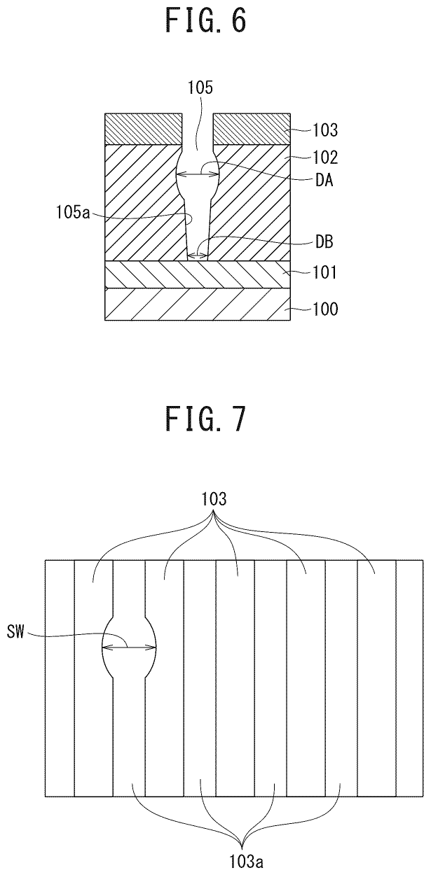

For example, a ratio DA/DB (see FIG. 6) between a diameter DA of a portion where the etching degree in the radial direction of the hole (direction orthogonal to the depth direction of the hole) is the largest and a diameter DB of a bottom part of the hole of the side wall surface of the hole where the bowing occurs is likely to have a small numerical value, and is likely to be 1.5 or less, for example.

In a mask stacked on the surface of the carbon material to form the hole, a pattern of the hole to be transferred to the carbon material is formed. When the concentration of the etching compound in the etching gas is in the numerical ranges above and, when the etching gas does not contain the metals or the total concentration of all types of the contained metals is 100 ppb by mass or less, a ratio LD/SD (see FIG. 5) between a long diameter LD and a short diameter SD of an opening part of the pattern formed in the mask is likely to be 1.10 or less even after the etching was completed.

When the roundness of the opening part of the pattern formed in the mask is impaired during etching, the bowing or necking is likely to occur in the hole, which poses a risk that the processing shape of the hole deteriorates. More specifically, the etching method according to this embodiment is an etching method capable of transferring the pattern formed in the mask to form the hole to the carbon material with a high accuracy.

The planar shape (shape of the opening) of the hole to be formed in the etching object includes a circular shape, an oval shape, a polygonal shape (e.g., rectangular shape), a closed free curved shape, a linear shape (e.g., slit shape), and the like.

The other type of gas other than the etching compound contained in the etching gas includes a second etching compound and an inert gas, for example. The etching gas may contain either one or both of the second etching compound and the inert gas.

When the etching gas contains the second etching compound together with the etching compound, the etching characteristics can be sometimes improved. Examples of the improved etching characteristics include improved accuracy of vertical processability, an improved etching rate of the carbon material, an improved etching selectivity, improved uniformity of an etching rate distribution in a wafer plane, and the like.

When the etching gas contains the second etching compound together with the fluoro-dithiethane, the above-described etching characteristics can be sometimes improved as compared with those when the etching gas does not contain the fluoro-dithiethane but contains the second etching compound.

The etching selectivity is a ratio of the etching rate of a non-etching object (e.g., silicon material) not subject to etching by the etching gas to the etching rate of the etching object subject to etching by the etching gas.

The second etching compound is a compound that is capable of etching a carbon material and is other than the above-described fluoro-dithiethane. The second etching compound is a compound having at least one type of an oxygen atom (O), a nitrogen atom (N), and a fluorine (F) atom in the molecule. The second etching compound may be added to the etching gas for the purpose of adjusting the etching characteristics, such as the etching rate and the etching selectivity, to an optional value.

Examples of the second etching compound include oxygen gas (O₂), ozone (O₃), nitrogen gas (N₂), nitrous oxide (N₂O), nitrogen monoxide (NO), nitrogen dioxide (NO₂), nitrosyl fluoride (NOF), carbonyl sulfide (COS), sulfur dioxide (SO₂), sulfur trioxide (SO₃), fluorine gas (F₂), oxygen difluoride (OF₂), chlorine trifluoride (ClF₃), bromine trifluoride (BrF₃), bromine pentafluoride (BrF₅), iodine pentafluoride (IF₅), iodine heptafluoride (IF₇), nitrogen trifluoride (NF₃), sulfur hexafluoride (SF₆), and fluorocarbon. The second etching compounds may be used alone or in combination of two or more types thereof.

The fluorocarbon is a compound in which some or all of the hydrogen atoms (H) possessed by the hydrocarbon are replaced by fluorine atoms. Among the fluorocarbons, those having 1 or more and 7 or less carbon atoms are preferable, those having 1 or more and 5 or less carbon atoms are more preferable, and those having 1 or more and 4 or less carbon atoms are still more preferable from the viewpoint of ease of accessibility. The fluorocarbons may have atoms other than the carbon atoms (C) and the fluorine atoms, and may have atoms, such as a hydrogen atom, a nitrogen atom, an oxygen atom, a sulfur atom (S), a chlorine atom (Cl), a bromine atom (Br), and an iodine atom (I), for example.

Specific examples of the fluorocarbon include tetrafluoromethane (CF₄), trifluoromethane (CHF₃), difluoromethane (CH₂F₂), fluoromethane (CH₃F), hexafluoroethane (C₂F₆), octafluoropropane (C₃F₈), octafluoro-2-butene (C₄F₈, E-isomer and Z-isomer), octafluorocyclobutane (c-C₄F₈), hexafluorobutadiene (e.g., hexafluoro-1,3-butadiene (C₄F₆)), perfluorocyclopentene (C₅F₈), hexafluorobenzene (C₆F₆), octafluorotoluene (C₇F₈), carbonyl fluoride (COF₂), and the like.

Among the second etching compounds, oxygen gas, nitrogen gas, tetrafluoromethane, carbonyl fluoride, octafluoro-2-butene, and hexafluoro-1,3-butadiene are more preferable from the viewpoint of ease of accessibility and a high etching rate of the carbon material.

The concentration of the second etching compound contained in the etching gas is not particularly limited. In the case of the non-alternating process, for example, the concentration of the second etching compound contained in the etching gas is preferably 80% by volume or more and less than 100% by volume, more preferably 90% by volume or more and 99% by volume or less, and still more preferably 95% by volume or more and 99% by volume or less.

In the case of the alternating process, for example, the concentration of the second etching compound contained in the etching gas can be set to more than 0% by volume and 100% by volume or less, and is preferably set to 50% by volume or more and 100% by volume or less and more preferably set to 80% by volume or more and 100% by volume or less from the viewpoint of increasing the etching rate of the carbon material.

Further, in the case of the sidewall protection process of the alternating process, for example, the concentration of the second etching compound contained in the etching gas can be set to more than 0% by volume and less than 100% by volume, and is preferably set to more than 0% by volume and 50% by volume or less and more preferably set to more than 0% by volume and 40% by volume or less.

When the concentration of the second etching compound contained in the etching gas is in the numerical ranges above, such an action that the excessive deposition of the protective film on the side wall surface of the hole can be suppressed, an action of increasing the etching rate of the carbon material, and the like are likely to be exhibited.

The type of the inert gas is not particularly limited insofar as it hardly reacts with the fluoro-dithiethane or the second etching compound under a condition where no plasma is generated. Examples of the inert gas include rare gases, such as helium (He), neon (Ne), argon (Ar), krypton (Kr), and xenon (Xe). Among the inert gases, helium and argon are preferable and argon is more preferable from the viewpoint of ease of accessibility. The inert gases may be used alone or in combination of two or more types thereof.

The concentration of the inert gas contained in the etching gas can be set to 0% by volume or more and less than 100% by volume, for example, and is preferably set to more than 0% by volume and 90% by volume or less, more preferably set to 1% by volume or more and 70% by volume or less, and still more preferably set to 3% by volume or more and 50% by volume or less. When the concentration of the inert gas is in the ranges above, such an action that the excessive deposition of the protective film on the side wall surface of the hole can be suppressed, an action of enhancing the ignitability of plasma, and the like are likely to be exhibited.

The etching gas can be obtained by mixing the plurality of components (etching compound, second etching compound, inert gas, and the like) constituting the etching gas. The mixing of the plurality of components may be performed either inside or outside a chamber where etching is performed. More specifically, the plurality of components constituting the etching gas may be individually and independently introduced into a chamber and mixed in the chamber, or the plurality of components constituting the etching gas may be mixed to obtain the etching gas and the obtained etching gas may be introduced into a chamber.

The etching gas also sometimes contains impurities. The impurities are components different from the etching compound and the other type of gas among the components of the etching gas. The impurities that can be contained in the etching gas include impurity gases, such as hydrogen gas (H₂), carbon dioxide (CO₂), water (H₂O), hydrogen fluoride (HF), hydrogen chloride (HCl), hydrogen sulfide (H₂S), sulfur dioxide (SO₂), and methane (CH₄), and metals, for example. The metals are described in detail later.

Among the above-described impurity gases, water, hydrogen fluoride, hydrogen chloride, and sulfur dioxide have a risk of corroding gas pipes for sending the gases, a chamber where etching is performed, a storage container for the fluoro-dithiethane, and the like. Thus, the impurity gas is preferably removed as much as possible from the etching gas. Thus, the reproducibility of the etching is likely to increase.

However, excessive purification performed to remove the impurity gas from the etching gas leads to an increase in the production cost of the etching gas, and therefore a small amount of the impurity gas may be contained in the etching gas. The concentration of the impurity gas in the etching gas is preferably 1% by volume or less, more preferably 1000 ppm by volume or less, and still more preferably 100 ppm by volume or less.

### [Metal]

When metal is present in the etching gas, the metal sometimes remains on the surface of the carbon material and is bonded with the sulfur atom derived from the fluoro-dithiethane. The bonding of the metal and the sulfur atom derived from the fluoro-dithiethane poses risks of the insufficient formation of a bond between the carbon atom on the surface of the carbon material and the sulfur atom derived from the fluoro-dithiethane or the alternation of the proportion of activated species generated from the fluoro-dithiethane.

As a result, the roundness of the opening part of the pattern formed in the mask is impaired during etching, and the bowing or necking is likely to occur in the hole, which poses a risk of a deterioration of the processing shape of the hole. Accordingly, the concentration of the metal in the etching gas is preferably as low as possible. When the etching gas or the etching compound contains metal, the metal is preferably removed as much as possible by purification. As a method for removing the metal, common purification methods, such as distillation, sublimation, filtration, membrane separation, adsorption, recrystallization, and chromatography, are usable.

The types of metals whose concentrations are to be reduced include metal elements belonging to the 3 to 6 periods of the periodic table, and include sodium, magnesium, aluminum, potassium, calcium, chromium, manganese, iron, cobalt, nickel, copper, zinc (Zn), antimony (Sb), molybdenum, and tungsten (W), for example.

Among these metals, sodium, magnesium, aluminum, potassium, calcium, chromium, manganese, iron, cobalt, nickel, copper, and molybdenum are contained in raw materials of members (e.g., metal pipe, storage container) with which the etching gas comes into contact in many cases, and therefore are likely to be mixed into the etching gas.

Thus, the etching gas contains or does not contain at least one type of metal among sodium, magnesium, aluminum, potassium, calcium, chromium, manganese, iron, cobalt, nickel, copper, and molybdenum as impurities. When the etching gas contains the at least one type of metal above, the total concentration of all types of the contained metals is required to be set to 100 ppb by mass or less. This can suppress the occurrence of the bowing in the side wall surface of a hole in the formation of the hole by etching.

There is a possibility that these metals are contained in the etching gas in the form of a simple substance and/or a metal compound. The metal compound means a compound having a metal element and a nonmetal element, and includes metal oxide, metal nitride, metal oxynitride, metal chloride, metal bromide, metal iodide, metal sulfide, and the like, for example.

The concentration of the metal in the etching gas can be quantified with an inductively coupled plasma mass spectrometer (ICP-MS). Herein, the “does not contain metal” means that the metal cannot be quantified with an inductively coupled plasma mass spectrometer (ICP-MS).

The total concentration of all types of the metals contained in the etching gas is preferably 1 ppb by mass or more and 100 ppb by mass or less, more preferably 1 ppb by mass or more and 80 ppb by mass or less, and still more preferably 2 ppb by mass or more and 50 ppb by mass or less.

### [Member to be Etched]

The member to be etched subjected to etching by the etching method according to this embodiment is a member to be processed into an optional form by the etching step, and has the etching object subject to etching by the etching gas. The etching object has a carbon material. The member to be etched subjected to etching by the etching method according to this embodiment may have the non-etching object not subject to etching by the etching gas together with the etching object subject. The member to be etched may further have one other than the etching object and the non-etching object.

When the member to be etched has the etching object and the non-etching object, the member to be etched may be a member having a portion formed of the etching object and a portion formed of the non-etching object, or may be a member formed of a mixture of the etching object and the non-etching object.

The shape of the member to be etched is not particularly limited and may be a plate shape, a foil shape, a film shape, a powder shape, or a block shape, for example. Examples of the member to be etched include the above-described semiconductor substrate.

### [Etching Object]

The etching object has a carbon material and may be one formed of only a carbon material, may be one having a portion formed of only a carbon material and a portion formed of other materials, or may be one formed of a mixture of a carbon material and other materials. The shape of the etching object is not particularly limited and may be a plate shape, a foil shape, a film shape, a powder shape, or a block shape, for example.

The carbon material refers to a material having carbon (C) in a proportion of 20% by mass or more and 100% by mass or less, and preferably has carbon in a proportion of 50% by mass or more and less than 100% by mass and more preferably has carbon in a proportion of 70% by mass or more and less than 100% by mass. Specific examples of the carbon material include amorphous carbon, carbon-doped silicon oxide (SiOC), a photoresist material, and the like. The carbon materials may be used alone or in combination of two or more types thereof. The carbon-doped silicon oxide is a compound having a carbon atom, an oxygen atom, and a silicon atom. The carbon-doped silicon oxide may further have atoms other than the carbon atom, the oxygen atom, and the silicon atom, and may further have a hydrogen atom, for example.

A method for forming the etching object having the carbon material in the material to be etched is not particularly limited, and methods commonly used for forming the carbon material into a film can be adopted. For example, spray coating, spin coating, thermal chemical vapor deposition (CVD), plasma enhanced chemical vapor deposition (PECVD), and the like, are usable.

In the method for forming the carbon material into a film using the PECVD, a hydrocarbon precursor is commonly used. The type of the hydrocarbon precursor is not particularly restricted, and alkane, alkene, and alkyne are all usable. Specific examples of the hydrocarbon precursor include methane (CH₄), ethane (C₄H₆), ethylene (C₂H₄), propylene (C₃H₆), propyne (C₃H₄), propane (C₃H₈), butane (C₄H₁₀), butene (C₄H₈, including isomers), butadiene (C₄H₆), acetylene (C₂H₂), toluene (C₇H₈), and mixtures thereof.

### [Non-Etching Object]

The non-etching object does not substantially react with the above-described etching compound or extremely slowly reacts with the above-described etching compound. Therefore, even when etching is performed by the etching method according to this embodiment, the etching hardly progresses.

The non-etching object has a substance that does not substantially react with the above-described etching compound or extremely slowly reacts with the above-described etching compound, and may be formed of only such a substance, may have a portion formed of only the above-described substance and a portion formed of other substances, or may be formed of a mixture of the above-described substance and other substances. The shape of the non-etching object is not particularly limited and may be a plate shape, a foil shape, a film shape, a powder shape, or a block shape, for example.

The non-etching object is usable as a resist or a mask for suppressing the etching of the etching object by the etching gas. Thus, the etching method according to this embodiment can be utilized for a method including transferring, utilizing the non-etching object subjected to patterning as a transfer layer (resist or mask), the pattern of the non-etching object to the etching object and patterning the etching object into a predetermined shape (e.g., forming a hole), for example, and therefore is suitably usable for the manufacture of semiconductor elements. The non-etching object is hardly etched, and therefore etching of a portion that should not be essentially etched of a semiconductor element can be suppressed and the loss of the characteristics of a semiconductor element by etching can be prevented.

In the above-described substance possessed by the non-etching object, the content of carbon is preferably small, and the content of carbon is preferably less than 20% by mass, more preferably 10% by mass or less, still more preferably 5% by mass or less, and particularly preferably 3% by mass or less.

Examples of such a substance include polysilicon, silicon oxide, silicon nitride, silicon oxynitride, an anti-reflective film, metal nitride, metal oxide, metal silicide, and the like. These substances may be used alone or in combination of two or more types thereof.

Examples of silicon oxide include silicon dioxide (SiO₂). Silicon nitride refers to a compound having silicon and nitrogen in an optional ratio, and examples include Si₃N₄. The purity of silicon nitride is not particularly limited, and is preferably 30% by mass or more, more preferably 60% by mass or more, and still more preferably 90% by mass or more.

The antireflective film refers to one commonly used as a bottom anti-reflective coating (BARC) layer and the like. Specific examples include resin, such as polysulfone and polyamide. The resin has a carbon content of preferably less than 20% by mass, more preferably 10% by mass or less, and still more preferably 5% by mass or less.

Further, as metals possessed by metal nitride, metal oxide, and metal silicide, metals commonly used as a hard mask in the manufacture of semiconductors can be utilized. Examples include titanium (Ti), tin (Sn), zirconium (Zr), hafnium (Hf), lanthanum (La), tungsten, copper, cobalt, nickel, and the like.

A method for patterning the transfer layer is not particularly limited insofar as it is capable of patterning the transfer layer into a desired shape. For example, patterning methods, such as selective deposition, photolithography, and etching, are usable.

### [Temperature Condition of Etching Step]

A temperature condition of the etching step in the etching method according to this embodiment is not particularly limited. The temperature of the member to be etched in etching is preferably set to −60° C. or more and 100° C. or less, more preferably set to −20° C. or more and 60° C. or less, and still more preferably set to 0° C. or more and 40° C. or less. When etching is performed with the temperature of the member to be etched set in the ranges above, the bowing hardly occurs in the side wall surface of a hole in the formation of the hole.

### [Pressure Condition of Etching Step]

A pressure condition of the etching step in the etching method according to this embodiment is not particularly limited. The pressure in a chamber where etching is performed is preferably set to 0.1 Pa or more and 100 Pa or less, more preferably set to 0.1 Pa or more and 5 Pa or less, and still more preferably set to 1 Pa or more and 5 Pa or less. When the pressure condition is in the ranges above, plasma is likely to be stabilized and uniform plasma is likely to be obtained.

The usage amount of the etching gas in the etching method according to this embodiment, e.g., the total flow rate of the etching gas to a chamber where plasma etching is performed in a plasma etching device, may be adjusted according to the internal volume of the chamber, the capability of an exhaust facility reducing the pressure in the chamber, the pressure in the chamber, and the like.

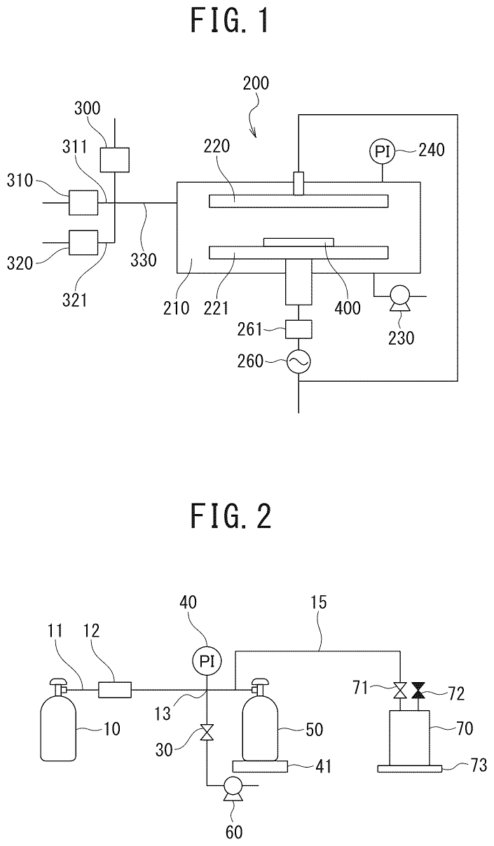

Next, one example of the configuration of an etching device capable of implementing the etching method according to this embodiment and one example of an etching method using the etching device are described with reference to FIG. 1. The etching device in FIG. 1 is a plasma etching device performing etching using capacitively coupled plasma as a plasma source. First, the etching device in FIG. 1 is described.

An etching device 200 in FIG. 1 includes a chamber 210 inside which plasma etching is performed, an upper electrode 220 forming an electric field and a magnetic field for converting the etching gas into plasma inside the chamber 210, a lower electrode 221 supporting a member to be etched 400 to be subjected to plasma etching inside the chamber 210, a vacuum pump 230 reducing the pressure inside the chamber 210, and a pressure gauge 240 measuring the pressure inside the chamber 210.

To the upper electrode 220 and the lower electrode 221, a high frequency power supply 260 generating high frequency waves is connected. The lower electrode 221 and the high frequency power supply 260 are connected via a matching device 261. The matching device 261 has a circuit to match an output impedance of the high frequency power supply 260 with impedances of the upper electrode 220 and the lower electrode 221. To the upper electrode 220 and the lower electrode 221, high frequency power supplies having different frequencies may be individually connected. In such a case, both the connection between the upper electrode 220 and the high frequency power supply and the connection between the lower electrode 221 and the high frequency power supply are preferably performed via the matching device.

The etching device 200 in FIG. 1 includes an etching gas supply section supplying an etching gas into the chamber 210. The etching gas supply section has a fluoro-dithiethane gas supply section 300 supplying a fluoro-dithiethane gas, an inert gas supply section 310 supplying an inert gas, a second etching compound gas supply section 320 supplying a second etching compound gas, an etching gas supply pipe 330 connecting the fluoro-dithiethane gas supply section 300 and the chamber 210, an inert gas supply pipe 311 connecting the inert gas supply section 310 to an intermediate part of the etching gas supply pipe 330, and a second etching compound gas supply pipe 321 connecting the second etching compound gas supply section 320 to the intermediate part of the etching gas supply pipe 330.

When the fluoro-dithiethane gas is supplied as an etching gas to the chamber 210, the fluoro-dithiethane gas is sent from the fluoro-dithiethane gas supply section 300 to the etching gas supply pipe 330, so that the fluoro-dithiethane gas is supplied to the chamber 210 via the etching gas supply pipe 330.

The pressure in the chamber 210 before the etching gas is supplied is not particularly limited insofar as it is equal to or less than the supply pressure of the etching gas or lower than the supply pressure of the etching gas. For example, the pressure is preferably 10⁻⁵ Pa or more and less than 100 kPa and more preferably 1 Pa or more and 80 kPa or less.

When a mixed gas of the fluoro-dithiethane gas and the inert gas is suppled as the etching gas to the chamber 210, the fluoro-dithiethane gas is sent from the fluoro-dithiethane gas supply section 300 to the etching gas supply pipe 330 and the inert gas is sent from the inert gas supply section 310 to the intermediate part of the etching gas supply pipe 330 via the inert gas supply pipe 311. Thus, the fluoro-dithiethane gas and the inert gas are mixed to form a mixed gas in the intermediate part of the etching gas supply pipe 330, and the mixed gas is supplied to the chamber 210 via the etching gas supply pipe 330.

Further, by performing the same operation as above, a mixed gas of the fluoro-dithiethane gas and the second etching compound gas or a mixed gas of the fluoro-dithiethane gas, the second etching compound gas, and the inert gas can be supplied as the etching gas to the chamber 210.

To facilitate the vaporization of the fluoro-dithiethane, the fluoro-dithiethane gas supply section 300 may be heated with an external heater (not illustrated) or the like and, to prevent the liquefication of the etching gas containing the fluoro-dithiethane in the pipe, the inert gas supply pipe 311, the second etching compound gas supply pipe 321, and the etching gas supply pipe 330 may be heated with an external heater (not illustrated) or the like.

When plasma etching is performed using such an etching device 200, the member to be etched 400 is placed on the lower electrode 221 arranged inside the chamber 210, the pressure inside the chamber 210 is reduced with the vacuum pump 230, and then the etching gas is supplied into the chamber 210 with the etching gas supply section. Then, when a high frequency power is applied to the upper electrode 220 and the lower electrode 221 with the high frequency power supply 260, an electric field and a magnetic field are formed inside the chamber 210, which accelerates electrons. The accelerated electrons collide with the fluoro-dithiethane and the like in the etching gas to generate new ions and electrons, and, as a result, discharge occurs and plasma is formed.

When the plasma is generated, the member to be etched 400 is etched. The supply amount of the etching gas to the chamber 210 and the concentration of the fluoro-dithiethane in the etching gas (mixed gas) can be adjusted by controlling the flow rates of the fluoro-dithiethane gas, the second etching compound gas, and the inert gas with mass flow controllers (not illustrated) placed in the etching gas supply pipe 330, the second etching compound gas supply pipe 321, and the inert gas supply pipe 311, respectively.

### EXAMPLES

Hereinafter, the present invention is more specifically described with reference to Examples and Comparative Examples below. Fluoro-dithiethane gases and second etching compound gases containing various concentrations of metals were individually prepared. Preparation examples of the fluoro-dithiethane gases and the second etching compound gases are described below.

### Preparation Example 1

The fluoro-dithiethane was purified using a purification device illustrated in FIG. 2. A raw material container 10 (formed of manganese steel, 3 L capacity) filled with 1 kg of 2,2,4,4-tetrafluoro-1,3-dithietane is connected to the inlet side of a gas filter 12 (Wafergard (registered trademark) manufactured by Entegris, Inc.) via a SUS 316 pipe 11. The raw material container 10 is attached with a main cock.

The outlet side of the gas filter 12 is connected to one branch pipe of a SUS316 branch pipe 13 branching in the shape of a cross. The other three branch pipes of the branch pipe 13 are individually connected to a vacuum pump 60, a vacuum gauge 40, and a receiving container 50 (formed of manganese steel, 3 L capacity). The raw material container 10, the pipe 11, and the branch pipe 13 can be heated to an optional temperature with an external heater (not illustrated).

An intermediate part of the branch pipe to which the vacuum pump 60 is connected is provided with a vacuum pump valve 30. The receiving container 50 is a container storing the fluoro-dithiethane purified by being passed through the gas filter 12 and is placed on a receiving container mass meter 41 measuring the mass of the receiving container 50. The receiving container 50 is attached with a main cock.

A branch pipe 15 extends from an intermediate part of the branch pipe to which the receiving container 50 is connected and is connected to a vaporizer 70 (formed of manganese steel, 30 mL capacity). The vaporizer 70 is a container storing the fluoro-dithiethane purified by being passed through the gas filter 12 and is placed on a vaporizer mass meter 73 measuring the mass of the vaporizer 70. The vaporizer 70 is attached with an inlet vaporizer valve 71 and an outlet vaporizer valve 72. The inlet vaporizer valve 71 is connected to the branch pipe 15 and the outlet vaporizer valve 72 is constantly closed.

The raw material container 10 was heated to 70° C., the pipe 11, the branch pipe 13, and the branch pipe 15 were heated to 100° C., the main cock of the raw material container 10 was closed, and the main cock of the receiving container 50 and the inlet vaporizer valve 71 were opened. Then, the vacuum pump valve 30 was opened, and the pressure inside the pipe 11, the branch pipe 13, the branch pipe 15, the receiving container 50, and the vaporizer 70 was reduced with the vacuum pump 60 until the pressure reached 10 Pa or less.

Thereafter, the vacuum pump valve 30 was closed, the main cock of the raw material container 10 and a main valve of the branch pipe 13 were opened, and 500 g of the 2,2,4,4-tetrafluoro-1,3-dithietane was sent to the receiving container 50 and 10 g of the 2,2,4,4-tetrafluoro-1,3-dithietane was sent to the vaporizer 70 from the raw material container 10. The 2,2,4,4-tetrafluoro-1,3-dithietane that was unpurified in the raw material container 10 is designated as Sample 1-1, and the 2,2,4,4-tetrafluoro-1,3-dithietane subjected to purification treatment and filled into the receiving container 50 and the vaporizer 70 is designated as Sample 1-2. Sample 1-2 was further purified by the same operation as above. The 2,2,4,4-tetrafluoro-1,3-dithietane subjected to the purification treatment twice is designated as Sample 1-3.

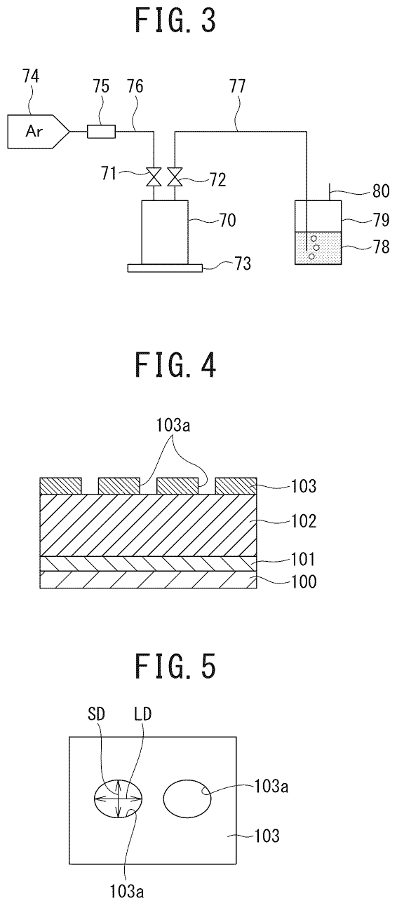

The concentrations of metals (M) contained in Sample 1-2 and Sample 1-3 were determined as follows. First, a mixed liquid of the fluoro-dithiethane and an aqueous nitric acid solution was prepared using a preparation device illustrated in FIG. 3. A method for preparing the mixed liquid is described below. The vaporizer 70 filled with the purified fluoro-dithiethane was removed from the purification device in FIG. 2 and attached to the preparation device in FIG. 3. More specifically, the inlet vaporizer valve 71 of the vaporizer 70 is connected to a mass flow controller 75 and an argon supply section 74 via an argon pipe 76, and the outlet vaporizer valve 72 is connected to a nitric acid container 79 via a connection pipe 77. The nitric acid container 79 stores 40 g of an aqueous nitric acid solution 78 having a concentration of 1% by mass. The tip of the connection pipe 77 is arranged in the aqueous nitric acid solution 78. The nitric acid container 79 is provided with an exhaust port 80.

The vaporizer 70 was heated to 80° C. with an external heater (not illustrated) and the connection pipe 77 was heated to 100° C. with an external heater (not illustrated). Then, argon at a flow rate of 40 mL/min was supplied from the argon supply section 74 to the vaporizer 70 via the argon pipe 76 for bubbling of the fluoro-dithiethane in the vaporizer 70 in the aqueous nitric acid solution 78 in the nitric acid container 79. After the bubbling was completed, the mass of the vaporizer 70 was measured with the vaporizer mass meter 73. Then, the mass decreased by 10 g (A) as compared with the mass before the bubbling. Accordingly, it is supposed that the entire amount of the fluoro-dithiethane in the vaporizer 70 was vaporized and supplied to the aqueous nitric acid solution 78 in the nitric acid container 79.

Next, the aqueous nitric acid solution having a concentration of 1% by mass was added such that the mass of the substances stored in the nitric acid container 79 reached 50 g (B), giving a mixed liquid of the fluoro-dithiethane and the aqueous nitric acid solution. 1 g of an aqueous layer part of the mixed liquid was extracted and analyzed for metals using an inductively coupled plasma mass spectrometer to measure the signal intensity of each of sodium, magnesium, aluminum, potassium, calcium, chromium, manganese, iron, cobalt, nickel, copper, and molybdenum contained in the mixed liquid (y). Then, the concentrations of the metals were calculated from the signal intensities above using calibration curves, and were totalized, thereby determining the total concentration of the metals.

The used calibration curves were created as follows. More specifically, reference aqueous nitric acid solutions having metal concentrations of 0 ppb by mass (containing no metals), 10 ppb by mass, 100 ppb by mass, 300 ppb by mass, 700 ppb by mass, and 1200 ppb by mass were produced and analyzed using an inductively coupled plasma mass spectrometer. Then, a calibration curve was created in which the concentration of the metal was plotted on the horizontal axis and the signal intensity was plotted on the vertical axis, and the slope (a) and the intercept (b) of the calibration curve were determined. The same operation was performed for sodium, magnesium, aluminum, potassium, calcium, chromium, manganese, iron, cobalt, nickel, copper, and molybdenum to create the calibration curves of the metals.

The concentration M of the metal contained in the fluoro-dithiethane can be calculated by the following equation.

$$M = \{ \{ y - b ) / a \} \times ( B / A )$$

The concentration of metal in argon is less than the detection limit of the inductively coupled plasma mass spectrometer and the detection limit is 0.1 ppb by mass, and therefore the concentration of metal in the argon was disregarded. Similarly in other Preparation Examples, Examples, and Comparative Examples described later, the concentration of metal in the argon was less than the detection limit of the inductively coupled plasma mass spectrometer, and therefore the concentration of metal in argon was disregarded.

Similarly, the unpurified fluoro-dithiethane (Sample 1-1) filled into the raw material container 10 was also determined for the concentrations of the contained metals and the total concentration thereof. The analysis results of Sample 1-1, Sample 1-2, and Sample 1-3 are shown in Table 1.

TABLE 1

| | Na | Mg | Al | K | Ca | Cr | Mn | Fe | Co | Ni | Cu | Mo | Total |
|---|---|---|---|---|---|---|---|---|---|---|---|---|---|
| Sample 1-1 | 32 | 17 | 31 | 39 | 38 | 211 | 101 | 189 | 121 | 98 | 75 | 101 | 1053 |
| Sample 1-2 | 6 | 8 | 6 | 6 | 6 | 43 | 21 | 55 | 13 | 11 | 11 | 12 | 198 |
| Sample 1-3 | 4 | 4 | 5 | 4 | 4 | 5 | 4 | 5 | 4 | 4 | 4 | 5 | 52 |
| Sample 2-1 | 41 | 34 | 43 | 25 | 27 | 258 | 98 | 171 | 144 | 101 | 81 | 121 | 1144 |
| Sample 2-2 | 4 | 4 | 3 | 4 | 3 | 5 | 5 | 4 | 4 | 4 | 4 | 4 | 48 |
| Sample 3-1 | 42 | 55 | 51 | 26 | 30 | 189 | 157 | 179 | 118 | 54 | 37 | 103 | 1041 |
| Sample 3-2 | 4 | 4 | 4 | 4 | 4 | 8 | 5 | 5 | 6 | 7 | 5 | 4 | 60 |
| Sample 4-1 | 27 | 55 | 55 | 31 | 37 | 257 | 198 | 157 | 96 | 22 | 76 | 88 | 1099 |
| Sample 4-2 | 4 | 4 | 4 | 5 | 4 | 5 | 4 | 6 | 4 | 5 | 4 | 4 | 53 |
| Sample 5-1 | 32 | 12 | 23 | 11 | 26 | 251 | 108 | 110 | 83 | 91 | 101 | 161 | 1009 |
| Sample 5-2 | 4 | 4 | 4 | 5 | 4 | 4 | 5 | 4 | 4 | 4 | 4 | 4 | 50 |
| Sample 6-1 | 44 | 10 | 8 | 11 | 10 | 387 | 81 | 380 | 23 | 12 | 15 | 81 | 1062 |
| Sample 6-2 | 4 | 4 | 4 | 4 | 5 | 4 | 4 | 5 | 5 | 4 | 5 | 4 | 52 |

* Unit of numerical values is ppb by mass.

### Preparation Example 2 to 5

Each fluoro-dithiethane was purified, and the unpurified fluoro-dithiethane and the purified fluoro-dithiethane were determined for the concentrations of the contained metals and the total concentration thereof in the same manner as in the case of Preparation Example 1. The results are shown in Table 1.

The fluoro-dithiethane of Preparation Example 2 is 1,1,2,2,3,3,4,4-octafluoro-1,3-dithietane. The unpurified product is designated as Sample 2-1 and the purified product is designated as Sample 2-2. The fluoro-dithiethane of Preparation Example 3 is 2,2,4-trifluoro-4-trifluoromethyl-1,3-dithietane. The unpurified product is designated as Sample 3-1 and the purified product is designated as Sample 3-2.

The fluoro-dithiethane of Preparation Example 4 is 2,4-difluoro-2,4-bis(trifluoromethyl)-1,3-dithietane. The unpurified product is designated as Sample 4-1 and the purified product is designated as Sample 4-2. The fluoro-dithiethane of Preparation Example 5 is 2,2,4,4-tetrakis(trifluoromethyl)-1,3-dithietane. The unpurified product is designated as Sample 5-1 and the purified product is designated as Sample 5-2.

### Preparation Example 6

Carbonyl sulfide cd by SynQuest Laboratories was purified in the same manner as in the case of Preparation Example 1, and the unpurified carbonyl sulfide and the purified carbonyl sulfide were determined for the concentrations of the contained metals and the total concentration thereof. The results are shown in Table 1. The unpurified product is designated as Sample 6-1 and the purified product is designated as Sample 6-2.

### Example 1-1

This example is an example of the above-described non-alternating process. An etching test piece was plasma etched using a capacitively coupled plasma etching device RIE-10NR manufactured by Samco, Inc. The etching test piece has the structure illustrated in FIG. 4. More specifically, an etch stop layer 101 having a film thickness of 100 nm is formed on a square-shaped silicon substrate 100 of 2 cm on each side, a carbon layer 102 having a film thickness of 500 nm is formed on the etch stop layer 101, and an anti-reflective film layer 103 having a film thickness of 40 nm is formed as a transfer layer on the carbon layer 102.

The etch stop layer 101 is formed of silicon oxynitride, the carbon layer 102 is formed of amorphous carbon, and the anti-reflective film layer 103 is formed of an anti-reflective coating material for lithography ARC (registered trademark) manufactured by Nissan Chemical Corporation. The content of carbon in the amorphous carbon above is 77% by mass and the content of carbon in the ARC (registered trademark) is 3% by mass.

In the anti-reflective film layer 103, a hole pattern is formed. More specifically, a plurality of through holes 103a is formed in the anti-reflective film layer 103 as illustrated in FIG. 4. The through hole 103a has a circular planar shape (shape of an opening) and has a diameter of 100 nm. The hole pattern of the anti-reflective film layer 103 was formed by the following procedure.

First, a photoresist layer (not illustrated) having a film thickness of 250 nm was formed on the anti-reflective film layer 103, and then the photoresist was exposed through a photomask (not illustrated) having a predetermined pattern drawn on the photomask. Then, an exposed portion of the photoresist layer was removed with a solvent, thereby performing patterning.

Next, the anti-reflective film layer 103 was etched with the patterned photoresist layer as a mask, and the pattern of the photoresist layer was transferred to the anti-reflective film layer 103, thereby forming the through holes 103a in the anti-reflective film layer 103. As the photoresist, TARF (registered trademark) manufactured by TOKYO OHKA KOGYO CO., LTD was used.

Next, conditions of the plasma etching are described. The etching gas is a mixed gas of the 2,2,4,4-tetrafluoro-1,3-dithietane of Sample 1-3 and an oxygen gas, which is the second etching compound. By setting the flow rate of Sample 1-3 to be introduced into a chamber to 5 mL/min and the flow rate of the oxygen gas to be introduced into the chamber to 95 mL/min, the concentration of the 2,2,4,4-tetrafluoro-1,3-dithietan in the etching gas in the chamber was adjusted to 5% by volume.

The total concentration of the metals in the etching gas at this time was calculated by the following formula.

$$Total concentration of metals in etching gas = ( {M}_{1} \times {V}_{1} \times {X}_{1} + {M}_{3} \times {V}_{3} \times {X}_{3} ) / ( {M}_{1} \times {V}_{1} + {M}_{2} \times {V}_{2} + {M}_{3} \times {V}_{3} )$$

In the equation, M₁ is the molecular weight of the fluoro-dithiethane, M₂ is the atomic weight of the inert gas (argon), M₃ is the molecular weight of the second etching compound, V₁ is the flow rate of the fluoro-dithiethane gas, V₂ is the flow rate of the inert gas, V₃ is the flow rate of the second etching compound, X₁ is the total concentration of the metals contained in the fluoro-dithiethane, and X₃ is the total concentration of the metals contained in the second etching compound.

The pressure inside the chamber was set to 1 Pa, the RF power (high frequency power supply) was set to 400 W, and the temperature of the etching test piece was set to 20° C., and then plasma etching was performed while the flow rate of a 2,2,4,4-tetrafluoro-1,3-dithietane gas, the flow rate of the oxygen gas, the pressure, the RF power, and the temperature of the etching test piece were constantly monitored to ensure that there was no difference between the set values and the run values thereof.

When the etching was completed, the etching test piece was taken out from the chamber and the through holes 103a in the anti-reflective film layer 103 of the etching test piece were observed using a JSM-7900F scanning microscope manufactured by JEOL. More specifically, the through holes 103a in the anti-reflective film layer 103 were observed from the upper side in a direction orthogonal to the surface of the anti-reflective film layer 103, and a long diameter LD and a short diameter SD of an opening part of each through hole 103a were measured (see FIG. 5). Then, a ratio between the long diameter LD and the short diameter SD (Long diameter LD/Short diameter SD) was calculated. The results are shown in Table 2.

The etching test piece taken out from the chamber after the etching was completed was cut, and the cross section thereof was observed under a scanning microscope. More specifically, the etching test piece was cut such that the cross section appearing by the cutting is a plane orthogonal to the surface of the anti-reflective film layer 103 and passing through the center of the through hole 103a, and the cross section of a hole 105 formed in the carbon layer 102 by the transfer of the pattern of the anti-reflective film layer 103 was observed.

Then, a diameter DA (hereinafter sometimes also referred to as “bowing part diameter DA”) of a portion where the etching degree in the radial direction of the hole 105 (direction orthogonal to the depth direction of the hole 105) was the largest of a side wall surface 105a of the hole 105 where the bowing occurred was measured and a diameter DB (hereinafter sometimes also referred to as “bottom part diameter DB”) of a bottom part of the hole 105 was measured (see FIG. 6). By calculating a ratio between the bowing part diameter DA and the bottom part diameter DB (DA/DB), the shape of the side wall surface 105a of hole 105 was analyzed. The results are shown in Table 2. The bottom part of the hole 105 means a portion in the vicinity of the boundary between a carbon layer 102 and a layer present directly under the carbon layer 102 (etch stop layer 101 in the case of this example) of the side wall surface 105a of the hole 105.

TABLE 2

| | Etching gas | | | | | Temperature | | |
|---|---|---|---|---|---|---|---|---|
| | | Second | | Flow | Metal | of etching | Pressure in | RF |
| | Fluoro- | etching | Inert | rate ¹⁾ | (ppb by | test piece | chamber | power |
| | dithiethane | compound | gas | (mL/min) | mass) | (° C.) | (Pa) | (W) |
| Ex. 1-1 | Sample 1-3 | O₂ | None | 5/95/0 | 11 | 20 | 1 | 400 |
| Ex. 1-2 | Sample 2-2 | O₂ | None | 5/95/0 | 13 | 20 | 1 | 400 |
| Ex. 1-3 | Sample 3-2 | O₂ | None | 5/95/0 | 14 | 20 | 1 | 400 |
| Ex. 1-4 | Sample 4-2 | O₂ | None | 3/97/0 | 11 | 20 | 1 | 400 |
| Ex. 1-5 | Sample 5-2 | O₂ | None | 1/99/0 | 5 | 20 | 1 | 400 |
| Ex. 1-8 | Sample 1-3 | N₂ | None | 5/495/0 | 3 | 20 | 1 | 400 |
| Ex. 1-7 | Sample 1-3 | N₂ + O₂ | None | 15/400 + | 8 | 20 | 1 | 400 |
| | | | | 85/0 | | | | |
| Ex. 1-8 | Sample 1-3 | CF₄ + O₂ | None | 5/50 + | 6 | 20 | 1 | 400 |
| | | | | 45/0 | | | | |
| Ex. 1-9 | Sample 1-3 | C₄F₆ + O₂ | None | 5/50 + | 3 | 20 | 1 | 400 |
| | | | | 45/0 | | | | |
| Ex. 1-10 | Sample 1-3 | CF₄ | None | 5/95/0 | 4 | 20 | 1 | 400 |
| Ex. 1-11 | Sample 1-3 | O₂ | Ar | 5/95/50 | 7 | 20 | 1 | 400 |
| Ex. 1-12 | Sample 1-3 | O₂ | None | 5/95/0 | 11 | 0 | 1 | 400 |
| Ex. 1-13 | Sample 1-3 | O₂ | None | 5/95/0 | 11 | 60 | 1 | 400 |
| Ex. 1-14 | Sample 1-3 | O₂ | None | 5/95/0 | 11 | 20 | 1 | 800 |
| Ex. 1-15 | Sample 1-3 | O₂ | None | 5/95/0 | 11 | 20 | 1 | 200 |
| Ex. 1-16 | Sample 1-3 | O₂ | None | 5/95/0 | 11 | 20 | 5 | 400 |
| Ex. 1-17 | Sample 1-3 | O₂ | None | 10/90/0 | 19 | 20 | 1 | 400 |
| Ex. 1-18 | Sample 1-3 | O₂ | None | 1/99/0 | 2 | 20 | 1 | 400 |
| Ex. 1-19 | Sample 1-2 | O₂ | None | 5/95/0 | 42 | 20 | 1 | 400 |
| Ex. 1-20 | Sample | O₂ | None | 5/95/0 | 96 | 20 | 1 | 400 |
| | 1-1 + 1-3 ²⁾ | | | | | | | |
| Comp. | Sample 1-1 | O₂ | None | 5/95/0 | 224 | 20 | 1 | 400 |
| Ex. 1-1 | | | | | | | | |
| Comp. | Sample 2-1 | O₂ | None | 5/95/0 | 324 | 20 | 1 | 400 |
| Ex. 1-2 | | | | | | | | |
| Comp. | Sample 3-1 | O₂ | None | 5/95/0 | 271 | 20 | 1 | 400 |
| Ex. 1-3 | | | | | | | | |
| Comp. | Sample 4-1 | O₂ | None | 3/97/0 | 224 | 20 | 1 | 400 |
| Ex. 1-4 | | | | | | | | |
| Comp. | Sample 5-1 | O₂ | None | 1/99/0 | 104 | 20 | 1 | 400 |
| Ex. 1-5 | | | | | | | | |
| Comp. | Sample 6-2 | O₂ | None | 5/95/0 | 8 | 20 | 1 | 400 |
| Ex. 1-6 | | | | | | | | |
| Comp. | Sample 6-1 | O₂ | None | 5/95/0 | 95 | 20 | 1 | 400 |
| Ex. 1-7 | | | | | | | | |
| Comp. | None | O₂ | None | 0/100/0 | Less | 20 | 1 | 400 |
| Ex. 1-8 | | | | | than 2 | | | |

| | | | | | Amorphous carbon | | |
|---|---|---|---|---|---|---|---|
| | | | | | | | Bowing |
| | | Anti-reflective film | | | | | part |
| | | | | Long | Bowing | Bottom | diameter/ |
| | Etching | Long | Short | diameter/ | part | part | Bottom |
| | time | diameter | diameter | Short | diameter | diameter | part |
| | (min) | (nm) | (nm) | diameter | (nm) | (nm) | diameter |
| Ex. 1-1 | 4 | 101 | 97 | 1.04 | 107 | 82 | 1.3 |
| Ex. 1-2 | 4 | 103 | 96 | 1.07 | 110 | 80 | 1.4 |
| Ex. 1-3 | 4 | 106 | 100 | 1.06 | 111 | 81 | 1.4 |
| Ex. 1-4 | 4 | 104 | 98 | 1.06 | 118 | 83 | 1.4 |
| Ex. 1-5 | 4 | 100 | 95 | 1.05 | 106 | 86 | 1.2 |
| Ex. 1-8 | 15 | 102 | 95 | 1.07 | 108 | 83 | 1.3 |
| Ex. 1.7 | 4 | 101 | 98 | 1.03 | 110 | 86 | 1.3 |
| Ex. 1-8 | 4 | 103 | 97 | 1.06 | 116 | 83 | 1.4 |
| Ex. 1-9 | 4 | 101 | 98 | 1.03 | 110 | 84 | 1.3 |
| Ex. 1-10 | 4 | 104 | 97 | 1.07 | 113 | 83 | 1.4 |
| Ex. 1-11 | 4 | 102 | 99 | 1.03 | 111 | 85 | 1.3 |
| Ex. 1-12 | 4 | 98 | 93 | 1.05 | 105 | 77 | 1.4 |
| Ex. 1-13 | 4 | 103 | 100 | 1.03 | 106 | 86 | 1.2 |
| Ex. 1-14 | 4 | 114 | 105 | 1.09 | 121 | 93 | 1.3 |
| Ex. 1-15 | 4 | 101 | 99 | 1.02 | 115 | 81 | 1.4 |
| Ex. 1-16 | 4 | 101 | 97 | 1.04 | 113 | 82 | 1.4 |
| Ex. 1.17 | 4 | 100 | 97 | 1.03 | 109 | 83 | 1.3 |
| Ex. 1.18 | 4 | 101 | 99 | 1.02 | 115 | 87 | 1.3 |
| Ex. 1-19 | 4 | 101 | 97 | 1.04 | 107 | 82 | 1.3 |
| Ex. 1-20 | 4 | 105 | 96 | 1.09 | 116 | 85 | 1.4 |
| Comp. | 4 | 113 | 98 | 1.15 | 131 | 82 | 1.6 |
| Ex. 1.1 | | | | | | | |
| Comp. | 4 | 115 | 96 | 1.20 | 134 | 79 | 1.7 |
| Ex. 1-2 | | | | | | | |
| Comp. | 4 | 108 | 90 | 1.20 | 129 | 70 | 1.8 |
| Ex. 1-3 | | | | | | | |
| Comp. | 4 | 109 | 93 | 1.17 | 131 | 75 | 1.7 |
| Ex. 1-4 | | | | | | | |
| Comp. | 4 | 117 | 98 | 1.26 | 143 | 83 | 1.7 |
| Ex. 1-5 | | | | | | | |
| Comp. | 4 | 108 | 98 | 1.10 | 133 | 85 | 1.6 |
| Ex. 1-6 | | | | | | | |
| Comp. | 4 | 109 | 98 | 1.11 | 135 | 83 | 1.6 |
| Ex. 1-7 | | | | | | | |
| Comp. | 4 | 144 | 103 | 1.40 | 177 | 118 | 1.5 |
| Ex. 1-8 | | | | | | | |

¹⁾ The flow rates are the flow rates of the fluoro-dithiethane, the second etching compound, and the inert gas. For example, a case where the flow rates of the fluoro-dithiethane, the second etching compound, and the inert gas are 5 mL/min, 95 mL/min, and 0 mL/min, respectively, is indicated by “5/95/0”. When two types of the second etching compounds are used, a case where the flow rates of the fluoro-dithiethane, the nitrogen gas, the oxygen gas, and the inert gas are 15 mL/min, 400 mL/min, 85 mL/min, and 0 mL/min, respectively, is indicated by “15/400 + 85/0”.
²⁾ Mixture of 40% by volume of Sample 1-1 and 60% by volume of Sample 1-3

### Examples 1-2 to 1-10, 1-12 to 1-20 and Comparative Examples 1-1 to 1-5

Etching test pieces were etched by performing the same operation as in the case of Example 1-1, except that those shown in Table 2 were used as the fluoro-dithiethane, those shown in Table 2 were used as the second etching compound, the flow rates of the fluoro-dithiethane gas and the second etching compound gas were as shown in Table 2, and various etching conditions, such as the temperature of the etching test piece, were as shown in Table 2. Regarding Examples 1-7, 1-8, 1-9, two types of the second etching compounds were used in combination as shown in Table 2.

Then, the long diameter LD and the short diameter SD of an opening part of each through hole 103a were measured and the ratio between the long diameter LD and the short diameter SD (Long diameter LD/Short diameter SD) was calculated, and the bowing part diameter DA and the bottom part diameter DB of the hole 105 were measured and the ratio between the bowing part diameter DA and the bottom part diameter DB (DA/DB) was calculated in the same manner as in the case of Example 1-1. The results are shown in Table 2.

### Example 1-11

An etching test piece was etched by the same operation as in the case of Example 1-1, except that the etching gas was a mixed gas of the 2,2,4,4-tetrafluoro-1,3-dithietane of Sample 1-3, an oxygen gas, and argon and that the flow rates of these three types of gases were as shown in Table 2.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 2.

### Comparative Examples 1-6, 1-7

Etching test pieces were etched by the same operation as in the case of Example 1-1, except that the unpurified carbonyl sulfide (Sample 6-1) or the purified carbonyl sulfide (Sample 6-2) was used in place of the fluoro-dithiethane of Sample 1-3.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 2.

### Comparative Example 1-8

An etching test piece was etched by the same operation as in the case of Example 1-1, except that the etching gas was an oxygen gas. Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 2.

### Example 2-1

This example is an example of the above-described alternating process. Etching was performed in the same manner as in Example 1-1, except for the points described below. An etching test piece similar to the etching test piece used in Example 1-1 was etched by the above-described alternating process. First, the deep etching process was carried out, and then the sidewall protection process was carried out. These processes were set as one cycle, and five cycles in total were performed.

As an etching gas for the deep etching process, an oxygen gas, which is the second etching compound, was used. The etching conditions are as follows. The flow rate of the oxygen gas is 100 mL/min, the RF power is 400 W, the pressure inside a chamber is 1 Pa, the temperature of the etching test piece is 20° C., and the etching time is 40 seconds.

As an etching gas for the sidewall protection process, a mixed gas of the 2,2,4,4-tetrafluoro-1,3-dithietane of Sample 1-3 and an oxygen gas, which is the second etching compound, was used. The etching conditions are as follows. The flow rate of Sample 1-3 is 20 mL/min, the flow rate of the oxygen gas is 30 mL/min, the RF power is 400 W, the pressure inside a chamber is 1 Pa, the temperature of the etching test piece is 20° C., and the gas distribution time is 20 seconds.

When the etching was completed, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 3.

TABLE 3

| | | | | | | | | | Temperature of etching | |
|---|---|---|---|---|---|---|---|---|---|---|
| | | | | | | | | | test piece (° C.) | |
| | Etching gas of deep etching process | | | | Etching gas of side wall surface protection process | | | | | Side wall |
| | Second | | Flow | Metal | | Second | Flow | Metal | Deep | surface |
| | etching | Additive | rate ¹⁾ | (ppb by | Fluoro- | etching | rate ²⁾ | (ppb by | etching | protection |
| | compound | gas | (mL/min) | mass) | dithiethane | compound | (mL/min) | mass) | process | process |
| Ex. 2-1 | O₂ | None | 100/0 | Less | Sample 1-3 | O₂ | 20/30 | 40 | 20 | 20 |
| | | | | than 2 | | | | | | |
| Ex. 2-2 | O₂ | None | 100/0 | Less | Sample 1-3 | None | 10/0 | 52 | 20 | 20 |
| | | | | than 2 | | | | | | |
| Ex. 2-3 | O₂ | Ar | 80/20 | Less | Sample 1-3 | O₂ | 20/30 | 40 | 20 | 20 |
| | | | | than 2 | | | | | | |
| Ex. 2-4 | O₂ | None | 100/0 | Less | Sample 1-3 | O₂ | 20/30 | 40 | 20 | 40 |
| | | | | than 2 | | | | | | |
| Ex. 2-5 | O₂ | None | 100/0 | Less | Sample 1-3 | O₂ | 20/30 | 40 | 40 | 40 |
| | | | | than 2 | | | | | | |
| Ex. 2-6 | O₂ | Sample | 95/5 | 11 | Sample 1-3 | O₂ | 20/30 | 40 | 20 | 20 |
| | | 1-3 | | | | | | | | |
| Comp. | O₂ | None | 100/0 | Less | Sample 1-1 | O₂ | 20/30 | 815 | 20 | 20 |
| Ex. 2-1 | | | | than 2 | | | | | | |

| | | | | Amorphous carbon | | |
|---|---|---|---|---|---|---|
| | | | | | | Bowing |
| | Anti-reflective film | | | | | part |
| | | | Long | Bowing | Bottom | diameter/ |
| | Long | Short | diameter/ | part | part | Bottom |
| | diameter | diameter | Short | diameter | diameter | part |
| | (nm) | (nm) | diameter | (nm) | (nm) | diameter |
| Ex. 2-1 | 101 | 98 | 1.03 | 107 | 82 | 1.3 |
| Ex. 2.2 | 100 | 96 | 1.04 | 113 | 76 | 1.5 |
| Ex. 2-3 | 100 | 97 | 1.03 | 108 | 76 | 1.4 |
| Ex. 2-4 | 103 | 99 | 1.04 | 108 | 85 | 1.3 |
| Ex. 2-5 | 100 | 99 | 1.01 | 115 | 86 | 1.3 |
| Ex. 2-6 | 100 | 98 | 1.02 | 106 | 83 | 1.3 |
| Comp. | 114 | 95 | 1.20 | 131 | 82 | 1.6 |
| Ex. 2-1 | | | | | | |

¹⁾ The flow rates are the flow rates of the fluoro-dithiethane and the additive gas. For example, a case where the flow rates of the fluoro-dithiethane and the additive gas are 100 mL/min and 0 mL/min, respectively, is indicated by “100/0”.
²⁾ The flow rates are the flow rates of the fluoro-dithiethane and the second etching gas. For example, a case where the flow rates of the fluoro-dithiethane and the second etching gas are 20 mL/min and 30 mL/min, respectively, is indicated by “20/30”.

### Examples 2-2 to 2-6 and Comparative Example 2-1

Etching test pieces were etched by performing the same operation as in the case of Example 2-1, except that the types and the flow rates of the etching gas for the deep etching process and the etching gas for the sidewall protection process, and the temperatures of the etching test pieces were as shown in Table 3.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 3.

### Example 3-1

An etching test piece was etched by the same operation as in the case of Example 1-17, except that the etch stop layer 101 was formed of silicon nitride, the carbon layer 102 was formed of carbon-doped silicon oxide, the diameter of the through holes 103a in the anti-reflective film layer 103 was 50 nm, and hexafluoro-1,3-butadiene and an oxygen gas were used as the second etching compound.

The carbon-doped silicon oxide is Black Diamond-3 (registered trademark) manufactured by Applied Materials, and the content of carbon in the Black Diamond-3 (registered trademark) is 27% by mass.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 4.

TABLE 4

| | Etching gas | | | | | Temperature | | |
|---|---|---|---|---|---|---|---|---|
| | | Second | | Flow | Metal | of etching | Pressure in | RF |
| | Fluoro- | etching | Inert | rate ¹⁾ | (ppb by | test piece | chamber | power |
| | dithiethane | compound | gas | (mL/min) | mass) | (° C.) | (Pa) | (W) |
| Ex. 3-1 | Sample 1-3 | C₄F₆ + O₂ | None | 10/40 + | 8 | 20 | 1 | 400 |
| | | | | 50/0 | | | | |
| Ex. 3-2 | Sample 2-2 | C₄F₆ + O₂ | None | 10/40 + | 10 | 20 | 1 | 400 |
| | | | | 50/0 | | | | |
| Ex. 3-3 | Sample 3-2 | C₄F₆ + O₂ | None | 10/40 + | 12 | 20 | 1 | 400 |
| | | | | 50/0 | | | | |
| Ex. 3-4 | Sample 4-2 | C₄F₆ + O₂ | None | 10/40 + | 13 | 20 | 1 | 400 |
| | | | | 50/0 | | | | |
| Ex. 3-5 | Sample 5-2 | C₄F₆ + O₂ | None | 10/40 + | 15 | 20 | 1 | 400 |
| | | | | 50/0 | | | | |
| Ex. 3-6 | Sample 1-3 | C₄F₆ + N₂ | None | 15/85 + | 8 | 20 | 1 | 400 |
| | | | | 400/0 | | | | |
| Ex. 3-7 | Sample 1-3 | C₄F₆ + O₂ | None | 20/40 + | 15 | 20 | 1 | 400 |
| | | | | 40/0 | | | | |
| Ex. 3-8 | Sample 1-3 | C₄F₆ + O₂ | Ar | 10/40 + | 7 | 20 | 1 | 400 |
| | | | | 50/50 | | | | |
| Ex. 3-9 | Sample 1-3 | C₄F₆ + O₂ | None | 10/40 + | 8 | 0 | 1 | 400 |
| | | | | 50/0 | | | | |
| Ex 3-10 | Sample 1-3 | C₄F₆ + O₂ | None | 10/40 + | 8 | 60 | 1 | 400 |
| | | | | 50/0 | | | | |
| Ex. 3-11 | Sample 1-3 | C₄F₆ + O₂ | None | 10/40 + | 8 | 20 | 1 | 800 |
| | | | | 50/0 | | | | |
| Ex. 3-12 | Sample 1-3 | C₄F₆ + O₂ | None | 10/40 + | 8 | 20 | 5 | 400 |
| | | | | 50/0 | | | | |
| Ex. 3-13 | Sample 1-3 | C₄F₆ + O₂ | None | 10/40 + | 8 | 20 | 1 | 400 |
| | | | | 50/0 | | | | |
| Ex. 3-14 | Sample 1-3 | C₄F₆ + O₂ | None | 10/40 + | 8 | 20 | 1 | 400 |
| | | | | 50/0 | | | | |
| Ex. 3-15 | Sample 1-3 | C₄F₆ + O₂ | None | 10/40 + | 8 | 20 | 1 | 400 |
| | | | | 50/0 | | | | |
| Ex. 3-16 | Sample 1-2 | C₄F₆ + O₂ | None | 10/40 + | 33 | 20 | 1 | 400 |
| | | | | 50/0 | | | | |
| Comp. | Sample 1-1 | C₄F₆ + O₂ | None | 10/40 + | 178 | 20 | 1 | 400 |
| Ex. 3-1 | | | | 50/0 | | | | |
| Comp. | Sample 2-1 | C₄F₆ + O₂ | None | 10/40 + | 262 | 20 | 1 | 400 |
| Ex. 3-2 | | | | 50/0 | | | | |
| Comp. | Sample 3-1 | C₄F₆ + O₂ | None | 10/40 + | 218 | 20 | 1 | 400 |
| Ex. 3-3 | | | | 50/0 | | | | |
| Comp. | Sample 4-1 | C₄F₆ + O₂ | None | 10/40 + | 271 | 20 | 1 | 400 |
| Ex. 3-4 | | | | 50/0 | | | | |
| Comp. | Sample 5-1 | C₄F₆ + O₂ | None | 10/40 + | 313 | 20 | 1 | 400 |
| Ex. 3-5 | | | | 50/0 | | | | |
| Comp. | Sample 6-2 | C₄F₆ + O₂ | None | 10/40 + | 4 | 20 | 1 | 400 |
| Ex. 3-6 | | | | 50/0 | | | | |
| Comp. | Sample 6-1 | C₄F₆ + O₂ | None | 10/40 + | 73 | 20 | 1 | 400 |
| Ex. 3-7 | | | | 50/0 | | | | |
| Comp. | None | C₄F₆ + O₂ | None | 0/40 + | Less | 20 | 1 | 400 |
| Ex. 3-8 | | | | 50/0 | than 2 | | | |

| | | | | | Carbon-added silicon oxide | | |
|---|---|---|---|---|---|---|---|
| | | | | | | | Bowing |
| | | Anti-reflective film | | | | | part |
| | | | | Long | Bowing | Bottom | diameter/ |
| | Etching | Long | Short | diameter/ | part | part | Bottom |
| | time | diameter | diameter | Short | diameter | diameter | part |
| | (min) | (nm) | (nm) | diameter | (nm) | (nm) | diameter |
| Ex. 3-1 | 4 | 51 | 48 | 1.06 | 54 | 46 | 1.2 |
| Ex. 3-2 | 4 | 53 | 49 | 1.08 | 56 | 42 | 1.3 |
| Ex. 3-3 | 4 | 53 | 49 | 1.08 | 55 | 45 | 1.2 |
| Ex. 3.4 | 4 | 55 | 50 | 1.10 | 55 | 45 | 1.2 |
| Ex. 3-5 | 4 | 54 | 49 | 1.10 | 57 | 48 | 1.2 |
| Ex. 3-6 | 4 | 52 | 48 | 1.08 | 56 | 43 | 1.3 |
| Ex. 3-7 | 4 | 51 | 49 | 1.04 | 53 | 42 | 1.3 |
| Ex. 3-8 | 4 | 50 | 47 | 1.06 | 61 | 44 | 1.4 |
| Ex. 3-9 | 4 | 50 | 46 | 1.09 | 57 | 40 | 1.4 |
| Ex 3-10 | 4 | 52 | 48 | 1.08 | 53 | 46 | 1.2 |
| Ex. 3-11 | 4 | 55 | 50 | 1.10 | 54 | 44 | 1.2 |
| Ex. 3-12 | 4 | 51 | 47 | 1.09 | 50 | 36 | 1.4 |
| Ex. 3-13 | 4 | 53 | 48 | 1.10 | 52 | 43 | 1.2 |
| Ex. 3-14 | 4 | 50 | 47 | 1.06 | 58 | 46 | 1.3 |
| Ex. 3-15 | 4 | 51 | 48 | 1.06 | 54 | 46 | 1.2 |
| Ex. 3-16 | 4 | 51 | 48 | 1.06 | 54 | 46 | 1.2 |
| Comp. | 4 | 54 | 45 | 1.20 | 67 | 41 | 1.6 |
| Ex. 3-1 | | | | | | | |
| Comp. | 4 | 50 | 38 | 1.32 | 68 | 37 | 1.8 |
| Ex. 3-2 | | | | | | | |
| Comp. | 4 | 51 | 43 | 1.19 | 66 | 41 | 1.6 |
| Ex. 3-3 | | | | | | | |
| Comp. | 4 | 50 | 42 | 1.19 | 65 | 35 | 1.9 |
| Ex. 3-4 | | | | | | | |
| Comp. | 4 | 55 | 46 | 1.20 | 61 | 38 | 1.6 |
| Ex. 3-5 | | | | | | | |
| Comp. | 4 | 58 | 47 | 1.23 | 83 | 44 | 1.9 |
| Ex. 3-6 | | | | | | | |
| Comp. | 4 | 59 | 47 | 1.26 | 83 | 44 | 1.9 |
| Ex. 3-7 | | | | | | | |
| Comp. | 4 | 63 | 47 | 1.34 | 88 | 57 | 1.5 |
| Ex. 3-8 | | | | | | | |

¹⁾ The flow rates are the flow rates of the fluoro-dithiethane, the second etching compound, and the inert gas. For example, a case where the flow rates of the fluoro-dithiethane. C₄F₆, the oxygen gas, and the inert gas are 10 mL/min, 40 mL/min, 50 mL/min, and 0 mL/min, respectively, is indicated by “10/40 + 50/0”.

### Examples 3-2 to 3-7, 3-9 to 3-16 and Comparative Examples 3-1 to 3-5

Etching test pieces were etched by performing the same operation as in the case of Example 3-1, except that those shown in Table 4 were used as the fluoro-dithiethane, those shown in Table 4 were used as the second etching compound, the flow rates of the fluoro-dithiethane gas and the second etching compound gas were as shown in Table 4, and various etching conditions, such as the temperature of the etching test piece, were as shown in Table 4.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 4.

### Example 3-8

An etching test piece was etched by performing the same operation as in the case of Example 3-1, except that the etching gas was a mixed gas of the 2,2,4,4-tetrafluoro-1,3-dithietane of Sample 1-3, an oxygen gas, hexafluoro-1,3-butadiene, and argon and the flow rates of these four types of gases were as shown in Table 4.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 4.

### Comparative Examples 3-6, 3-7

Etching test pieces were etched by performing the same operation as in the case of Example 3-1, except that the unpurified carbonyl sulfide (Sample 6-1) or the purified carbonyl sulfide (Sample 6-2) was used in place of the fluoro-dithiethane of Sample 1-3.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 4.

### Comparative Example 3-8

An etching test piece was etched by performing the same operation as in the case of Example 3-1, except that the etching gas was a mixed gas of an oxygen gas and hexafluoro-1,3-butadiene.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 4.

### Example 4-1

This example is an example of the above-described alternating process. An etching test piece was etched by performing the same operation as in the case of Example 2-1, except that an etching test piece similar to that used in Example 3-1 was used, hexafluoro-1,3-butadiene and an oxygen gas were used as the second etching compound in the deep etching process, and the flow rates of the fluoro-dithiethane gas and the second etching compound gas were as shown in Table 5.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 5.

TABLE 5

| | | | | | | | | | Temperature of etching | |
|---|---|---|---|---|---|---|---|---|---|---|
| | | | | | | | | | test piece (° C.) | |
| | Etching gas of deep etching process | | | | Etching gas of side wall surface protection process | | | | | Side wall |
| | Second | | Flow | Metal | | Second | Flow | Metal | Deep | surface |
| | etching | Additive | rate ¹⁾ | (ppb by | Fluoro- | etching | rate ²⁾ | (ppb by | etching | protection |
| | compound | gas | (mL/min) | mass) | dithiethane | compound | (mL/min) | mass) | process | process |
| Ex. 4-1 | C₄F₆ + O₂ | None | 50 + 50/0 | Less | Sample 1-3 | O₂ | 10/40 | 29 | 20 | 20 |
| | | | | than 2 | | | | | | |
| Ex. 4-2 | C₄F₆ + O₂ | None | 50 + 50/0 | Less | Sample 1-3 | O₂ | 15/35 | 36 | 20 | 20 |
| | | | | than 2 | | | | | | |
| Ex. 4-3 | C₄F₆ + O₂ | Ar | 50 + 50/20 | Less | Sample 1-3 | O₂ | 10/40 | 29 | 20 | 20 |
| | | | | than 2 | | | | | | |
| Ex. 4-4 | C₄F₆ + O₂ | None | 50 + 50/0 | Less | Sample 1-3 | O₂ | 10/40 | 29 | 20 | 40 |
| | | | | than 2 | | | | | | |
| Ex. 4-5 | C₄F₆ + O₂ | None | 50 + 50/0 | Less | Sample 1-3 | O₂ | 10/40 | 29 | 40 | 20 |
| | | | | than 2 | | | | | | |
| Ex. 4-6 | C₄F₆ + O₂ | None | 50 + 50/0 | Less | Sample 1-3 | O₂ | 10/40 | 29 | 40 | 40 |
| | | | | than 2 | | | | | | |
| Ex 4-7 | C₄F₆ + O₂ | Sample | 45 + 50/5 | 4 | Sample 1-3 | O₂ | 10/40 | 29 | 20 | 20 |
| | | 1-3 | | | | | | | | |
| Comp. | C₄F₆ + O₂ | None | 50 + 50/0 | Less | Sample 1-1 | O₂ | 10/40 | 592 | 40 | 40 |
| Ex. 4-1 | | | | than 2 | | | | | | |

| | | | | Carbon-added silicon oxide | | |
|---|---|---|---|---|---|---|
| | | | | | | Bowing |
| | Anti-reflective film | | | | | part |
| | | | Long | Bowing | Bottom | diameter/ |
| | Long | Short | diameter/ | part | part | Bottom |
| | diameter | diameter | Short | diameter | diameter | part |
| | (nm) | (nm) | diameter | (nm) | (nm) | diameter |
| Ex. 4-1 | 51 | 48 | 1.06 | 51 | 44 | 1.2 |
| Ex. 4-2 | 50 | 48 | 1.04 | 50 | 45 | 1.1 |
| Ex. 4-3 | 50 | 47 | 1.06 | 53 | 44 | 1.2 |
| Ex. 4-4 | 51 | 49 | 1.04 | 52 | 45 | 1.2 |
| Ex. 4-5 | 52 | 48 | 1.08 | 52 | 46 | 1.1 |
| Ex. 4-6 | 51 | 50 | 1.02 | 55 | 46 | 1.2 |
| Ex 4-7 | 51 | 47 | 1.09 | 52 | 40 | 1.3 |
| Comp. | 53 | 42 | 1.26 | 58 | 35 | 1.7 |
| Ex. 4-1 | | | | | | |

¹⁾ The flow rates are the flow rates of the second etching compound and the additive gas. For example, a case where the flow rates of C₄F₆, the oxygen gas, and the additive gas are 50 mL/min, 50 mL/min, and 0 mL/min, respectively, is indicated by “50/50/0”.
²⁾ The flow rates are the flow rates of the fluoro-dithiethane and the second etching gas. For example, a case where the flow rates of the fluoro-dithiethane and the second etching gas are 10 mL/min and 40 mL/min, respectively, is indicated by “10/40”.

### Examples 4-2 to 4-7 and Comparative Example 4-1

Etching test pieces were etched by performing the same operation as in the case of Example 4-1, except that the types and the flow rates of the etching gas for the deep etching process and the etching gas for the sidewall protection process and the temperatures of the etching test pieces were as shown in Table 5.

Then, the long diameter LD and the short diameter SD were measured and the ratio between the long diameter LD and the short diameter SD was calculated, and the bowing part diameter DA and the bottom part diameter DB were measured and the ratio between the bowing part diameter DA and the bottom part diameter DB was calculated in the same manner as in the case of Example 1-1. The results are shown in Table 5.

### Example 5-1

An etching test piece was etched in the same manner as in the case of Example 1-1, except that the planar shape of the through hole 103a formed in the anti-reflective film layer 103 of the etching test piece was a linear shape (see FIG. 7). As is understood from FIG. 7, the anti-reflective film layer 103 is divided into a plurality of linear portions by the through holes 103a, and each linear portion has a width of 400 nm and each linear through hole 103a has a width of 200 nm.

When the etching was completed, the through holes 103a in the anti-reflective film layer 103 of the etching test piece were observed in the same manner as in the case of Example 1-1. More specifically, the through holes 103a in the anti-reflective film layer 103 were observed from the upper side in a direction orthogonal to the surface of the anti-reflective film layer 103, and the maximum width SW of the opening part of the linear through hole 103a was measured (see FIG. 7). The results are shown in Table 6.

The etching test piece was cut, and the cross section thereof was observed in the same manner as in the case of Example 1-1. More specifically, the etching test piece was cut such that the cross section appearing by the cutting is a plane orthogonal to the surface of the anti-reflective film layer 103 and is a plane orthogonal to the extension direction of the linear portion of the anti-reflective film layer 103 extending in the linear shape, and the cross section of the hole 105 formed in the carbon layer 102 by the transfer of the pattern of the anti-reflective film layer 103 was observed.

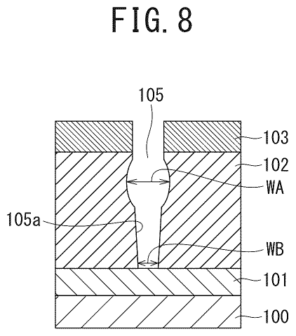

Then, a width WA (hereinafter sometimes also referred to as “bowing part width WA”) of a portion where the etching degree in the width direction of the hole 105 was the largest of the side wall surface 105a of the hole 105 where the bowing occurred was measured and a width WB (hereinafter sometimes also referred to as “bottom part width WB”) of a bottom part of the hole 105 was measured (see FIG. 8). By calculating a ratio between the bowing part width WA and the bottom part width WB (WA/WB), the shape of the side wall surface 105a of hole 105 was analyzed. The results are shown in Table 6.

TABLE 6

| | Etching gas | | | | | Temperature | |
|---|---|---|---|---|---|---|---|
| | | Second | | Flow | Metal | of etching | Pressure in |
| | Fluoro- | etching | Inert | rate ¹⁾ | (ppb by | test piece | chamber |
| | dithiethane | compound | gas | (mL/min) | mass) | (° C.) | (Pa) |
| Ex. 5-1 | Sample 1-3 | O₂ | None | 5/95/0 | 11 | 20 | 1 |
| Ex. 5-2 | Sample 2-2 | O₂ | None | 5/95/0 | 13 | 20 | 1 |
| Ex. 5-3 | Sample 3-2 | O₂ | None | 5/95/0 | 14 | 20 | 1 |
| Ex. 5-4 | Sample 4-2 | O₂ | None | 3/97/0 | 11 | 20 | 1 |
| Ex. 5-5 | Sample 5-2 | O₂ | None | 1/99/0 | 5 | 20 | 1 |
| Ex. 5-6 | Sample 1-3 | N₂ | None | 5/495/0 | 3 | 20 | 1 |
| Ex. 5-7 | Sample 1-3 | N₂ + O₂ | None | 15/400 + | 8 | 20 | 1 |
| | | | | 85/0 | | | |
| Ex. 5-8 | Sample 1-3 | CF₄ + O₂ | None | 5/50 + | 6 | 20 | 1 |
| | | | | 45/0 | | | |
| Ex. 5-9 | Sample 1-3 | C₄F₆ + O₂ | None | 5/50 + | 3 | 20 | 1 |
| | | | | 45/0 | | | |
| Ex. 5-10 | Sample 1-3 | CF₄ | None | 5/95/0 | 4 | 20 | 1 |
| Ex. 5-11 | Sample 1-3 | O₂ | Ar | 5/95/50 | 7 | 20 | 1 |
| Ex. 5-12 | Sample 1-3 | O₂ | None | 5/95/0 | 11 | 0 | 1 |
| Ex. 5-13 | Sample 1-3 | O₂ | None | 5/95/0 | 11 | 60 | 1 |
| Ex. 5-14 | Sample 1-3 | O₂ | None | 5/95/0 | 11 | 20 | 1 |
| Ex. 5-15 | Sample 1-3 | O₂ | None | 5/95/0 | 11 | 20 | 1 |
| Ex. 5-16 | Sample 1-3 | O₂ | None | 5/95/0 | 11 | 20 | 5 |
| Ex. 5-17 | Sample 1-3 | O₂ | None | 10/90/0 | 19 | 20 | 1 |
| Ex. 5-18 | Sample 1-3 | O₂ | None | 1/99/0 | 2 | 20 | 1 |
| Ex. 5-19 | Sample 1-2 | O₂ | None | 5/95/0 | 42 | 20 | 1 |
| Ex. 5-20 | Sample | O₂ | None | 5/95/0 | 96 | 20 | 1 |
| | 1-1 + 1-3 ²⁾ | | | | | | |
| Comp. | Sample 1-1 | O₂ | None | 5/95/0 | 224 | 20 | 1 |
| Ex. 5-1 | | | | | | | |
| Comp. | Sample 2-1 | O₂ | None | 5/95/0 | 324 | 20 | 1 |
| Ex. 5-2 | | | | | | | |
| Comp. | Sample 3-1 | O₂ | None | 5/95/0 | 271 | 20 | 1 |
| Ex. 5-3 | | | | | | | |
| Comp. | Sample 4-1 | O₂ | None | 3/97/0 | 224 | 20 | 1 |
| Ex. 5-4 | | | | | | | |
| Comp. | Sample 5-1 | O₂ | None | 1/99/0 | 104 | 20 | 1 |
| Ex. 5-5 | | | | | | | |
| Comp. | Sample 6-2 | O₂ | None | 5/95/0 | 8 | 20 | 1 |
| Ex. 5-6 | | | | | | | |
| Comp. | Sample 6-1 | O₂ | None | 5/95/0 | 95 | 20 | 1 |
| Ex. 5-7 | | | | | | | |
| Comp. | None | O₂ | None | 0/100/0 | Less | 20 | 1 |
| Ex. 5-8 | | | | | than 2 | | |

| | | | | Amorphous carbon | | |
|---|---|---|---|---|---|---|
| | | | Anti- | | | Bowing |
| | | | reflective | | | part |
| | | | film | Bowing | Bottom | diameter/ |
| | RF | Etching | Maximum | part | part | Bottom |
| | power | time | width | diameter | diameter | part |
| | (W) | (min) | (nm) | (nm) | (nm) | diameter |
| Ex. 5-1 | 400 | 4 | 200 | 200 | 190 | 1.1 |
| Ex. 5-2 | 400 | 4 | 205 | 221 | 190 | 1.2 |
| Ex. 5-3 | 400 | 4 | 200 | 210 | 190 | 1.1 |
| Ex. 5.4 | 400 | 4 | 200 | 205 | 183 | 1.1 |
| Ex. 5-5 | 400 | 4 | 207 | 224 | 193 | 1.2 |
| Ex. 5-6 | 400 | 15 | 200 | 200 | 172 | 1.2 |
| Ex. 5-7 | 400 | 4 | 200 | 210 | 186 | 1.1 |
| Ex. 5-8 | 400 | 4 | 200 | 212 | 191 | 1.1 |
| Ex. 5-9 | 400 | 4 | 200 | 200 | 177 | 1.1 |
| Ex. 5-10 | 400 | 4 | 200 | 200 | 169 | 1.2 |
| Ex. 5-11 | 400 | 4 | 200 | 200 | 182 | 1.1 |
| Ex. 5-12 | 400 | 4 | 200 | 217 | 178 | 1.2 |
| Ex. 5-13 | 400 | 4 | 200 | 200 | 193 | 1.0 |
| Ex. 5-14 | 800 | 4 | 200 | 205 | 181 | 1.1 |
| Ex. 5-15 | 200 | 4 | 200 | 200 | 172 | 1.2 |
| Ex. 5-16 | 400 | 4 | 200 | 200 | 181 | 1.1 |
| Ex. 5-17 | 400 | 4 | 200 | 200 | 182 | 1.1 |
| Ex. 5-18 | 400 | 4 | 200 | 210 | 185 | 1.1 |
| Ex. 5-19 | 400 | 4 | 200 | 227 | 178 | 1.3 |
| Ex. 5-20 | 400 | 4 | 205 | 229 | 175 | 1.3 |
| Comp. | 400 | 4 | 221 | 231 | 162 | 1.4 |
| Ex. 5-1 | | | | | | |
| Comp. | 400 | 4 | 214 | 233 | 170 | 1.4 |
| Ex. 5-2 | | | | | | |
| Comp. | 400 | 4 | 210 | 235 | 169 | 1.4 |
| Ex. 5-3 | | | | | | |
| Comp. | 400 | 4 | 212 | 233 | 172 | 1.4 |
| Ex. 5-4 | | | | | | |
| Comp. | 400 | 4 | 224 | 231 | 169 | 1.4 |
| Ex. 5-5 | | | | | | |
| Comp. | 400 | 4 | 212 | 251 | 185 | 1.4 |
| Ex. 5-6 | | | | | | |
| Comp. | 400 | 4 | 210 | 249 | 182 | 1.4 |
| Ex. 5-7 | | | | | | |
| Comp. | 400 | 4 | 287 | 311 | 209 | 1.5 |
| Ex. 5-8 | | | | | | |

¹⁾ The flow rates are the flow rates of the fluoro-dithiethane, the second etching compound, and the inert gas. For example, a case where the flow rates of the fluoro-dithiethane, the second etching compound, and the inert gas are 5 mL/min, 95 mL/min, and 0 mL/min, respectively, is indicated by “5/95/0”. When two types of the second etching compounds are used, a case where the flow rates of the fluoro-dithiethane, the nitrogen gas, the oxygen gas, and the inert gas are 15 mL/min, 400 mL/min, 85 mL/min, and 0 mL/min, respectively, is indicated by “15/400 + 85/0”.
²⁾ Mixture of 40% by volume of Sample 1-1 and 60% by volume of Sample 1-3

### Examples 5-2 to 5-10, 5-12 to 5-20 and Comparative Examples 5-1 to 5-5

Etching test pieces were etched by performing the same operation as in the case of Example 5-1, except that those shown in Table 6 were used as the fluoro-dithiethane, those shown in Table 6 were used as the second etching compound, the flow rates of the fluoro-dithiethane gas and the second etching compound gas were as shown in Table 6, and various etching conditions, such as the temperature of the etching test piece, were as shown in Table 6. Regarding Examples 5-7, 5-8, 5-9, two types of the second etching compounds were used in combination as shown in Table 6. Regarding Example 5-20, a mixture of Sample 1-1 and Sample 1-3 was used as the fluoro-dithiethane as shown in Table 6.

Then, the maximum width SW of the opening part in the linear through hole 103a was measured, the bowing part width WA and the bottom part width WB were measured, and a ratio between the bowing part width WA and the bottom part width WB (WA/WB) was calculated in the same manner as in the case of Example 5-1. The results are shown in Table 6.

### Example 5-11

An etching test piece was etched by the same operation as in the case of Example 5-1, except that the etching gas was a mixed gas of the 2,2,4,4-tetrafluoro-1,3-dithietane of Sample 1-3, an oxygen gas, and argon and that the flow rates of these three types of gases were as shown in Table 6.

Then, the maximum width SW of the opening part in the linear through hole 103a was measured, the bowing part width WA and the bottom part width WB were measured, and a ratio between the bowing part width WA and the bottom part width WB (WA/WB) was calculated in the same manner as in the case of Example 5-1. The results are shown in Table 6.

### Comparative Examples 5-6, 5-7

Etching test pieces were etched by the same operation as in the case of Example 5-1, except that the unpurified carbonyl sulfide (Sample 6-1) or the purified carbonyl sulfide (Sample 6-2) was used in place of the fluoro-dithiethane of Sample 1-3.

Then, the maximum width SW of the opening part in the linear through hole 103a was measured, the bowing part width WA and the bottom part width WB were measured, and a ratio between the bowing part width WA and the bottom part width WB (WA/WB) was calculated in the same manner as in the case of Example 5-1. The results are shown in Table 6.

### Comparative Example 5-8

An etching test piece was etched by the same operation as in the case of Example 5-1, except that the etching gas was an oxygen gas. Then, the maximum width SW of the opening part in the linear through hole 103a was measured, the bowing part width WA and the bottom part width WB were measured, and a ratio between the bowing part width WA and the bottom part width WB (WA/WB) was calculated in the same manner as in the case of Example 5-1. The results are shown in Table 6.

### Example 6-1

This example is an example of the above-described alternating process. Etching was performed in the same manner as in Example 2-1, except that the etching test piece used in Example 5-1 was used. When the etching was completed, the maximum width SW of the opening part in the linear through hole 103a was measured, the bowing part width WA and the bottom part width WB were measured, and a ratio between the bowing part width WA and the bottom part width WB (WA/WB) was calculated in the same manner as in the case of Example 5-1. The results are shown in Table 7.

TABLE 7

| | Etching gas of deep etching process | | | | Etching gas of side wall surface protection process | | | |
|---|---|---|---|---|---|---|---|---|
| | Second | | Flow | Metal | | Second | Flow | Metal |
| | etching | Additive | rate ¹⁾ | (ppb by | Fluoro- | etching | rate ²⁾ | (ppb by |
| | compound | gas | (mL/min) | mass) | dithiethane | compound | (mL/min) | mass) |
| Ex. 6-1 | O₂ | None | 100/0 | Less | Sample 1-3 | O₂ | 20/30 | 40 |
| | | | | than 2 | | | | |
| Ex. 6-2 | O₂ | None | 100/0 | Less | Sample 1-3 | None | 10/0 | 52 |
| | | | | than 2 | | | | |
| Ex. 6-3 | O₂ | Ar | 80/20 | Less | Sample 1-3 | O₂ | 20/30 | 40 |
| | | | | than 2 | | | | |
| Ex. 6-4 | O₂ | None | 100/0 | Less | Sample 1-3 | O₂ | 20/30 | 40 |
| | | | | than 2 | | | | |
| Ex. 6-5 | O₂ | None | 100/0 | Less | Sample 1-3 | O₂ | 20/30 | 40 |
| | | | | than 2 | | | | |
| Ex. 6-6 | O₂ | Sample | 95/5 | 11 | Sample 1-3 | O₂ | 20/30 | 40 |
| | | 1-3 | | | | | | |
| Comp. | O₂ | None | 100/0 | Less | Sample 1-1 | O₂ | 20/30 | 815 |
| Ex. 6-1 | | | | than 2 | | | | |

| | | | | Amorphous carbon | | |
|---|---|---|---|---|---|---|
| | Temperature of etching | | Anti- | | | Bowing |
| | test piece (° C.) | | reflective | | | part |
| | | Side wall | film | Bowing | Bottom | diameter/ |
| | Deep | surface | Maximum | part | part | Bottom |
| | etching | protection | width | diameter | diameter | part |
| | process | process | (nm) | (nm) | (nm) | diameter |
| Ex. 6-1 | 20 | 20 | 200 | 200 | 190 | 1.1 |
| Ex. 6-2 | 20 | 20 | 200 | 200 | 187 | 1.1 |
| Ex. 6-3 | 20 | 20 | 200 | 200 | 189 | 1.1 |
| Ex. 6-4 | 20 | 40 | 200 | 200 | 191 | 1.0 |
| Ex. 6-5 | 40 | 40 | 200 | 200 | 189 | 1.1 |
| Ex. 6-6 | 20 | 20 | 200 | 200 | 190 | 1.1 |
| Comp. | 20 | 20 | 220 | 231 | 170 | 1.4 |
| Ex. 6-1 | | | | | | |

¹⁾ The flow rates are the flow rates of the fluoro-dithiethane and the additive gas. For example, a case where the flow rates of the fluoro-dithiethane and the additive gas are 100 mL/min and 0 mL/min, respectively, is indicated by “100/0”.
²⁾ The flow rates are the flow rates of the fluoro-dithiethane and the second etching gas. For example, a case where the flow rates of the fluoro-dithiethane and the second etching gas are 20 mL/min and 30 mL/min, respectively, is indicated by “20/30”.

### Examples 6-2 to 6-6 and Comparative Example 6-1

Etching test pieces were etched by performing the same operation as in the case of Example 6-1, except that the types and the flow rates of the etching gas for the deep etching process and the etching gas for the sidewall protection process and the temperatures of the etching test pieces were as shown in Table 7.

Then, the maximum width SW of the opening part in the linear through hole 103a was measured, the bowing part width WA and the bottom part width WB were measured, and a ratio between the bowing part width WA and the bottom part width WB (WA/WB) was calculated in the same manner as in the case of Example 5-1. The results are shown in Table 7.

The results of Examples 1-1 to 1-5, 1-19 show the following facts. More specifically, it is shown that, by the use of the mixed gas of the fluoro-dithiethane and an oxygen gas as the etching gas, the carbon layer directly under the opening part in the anti-reflective film layer was etched until the etch stop layer was exposed. At this time, the ratio between the long diameter LD and the short diameter SD (LD/SD) of the opening part in the anti-reflective film layer after the etching was 1.04 to 1.07, and the long diameter LD was 100 to 106 nm and the short diameter SD was 95 to 100 nm. The ratio between the bowing part diameter DA and the bottom part diameter DB (DA/DB) is 1.2 to 1.4, which shows that the pattern of the anti-reflective film layer was transferred to the carbon layer without any problem.

The results of Examples 1-6 to 1-10 show the following facts. More specifically, it is shown that, even when a nitrogen gas, the mixed gas of the nitrogen gas and an oxygen gas, the mixed gas of tetrafluoromethane and the oxygen gas, the mixed gas of octafluorocyclobutane and the oxygen gas, and tetrafluoromethane were used as the second etching compound, the etching progressed without any problem, and the pattern of the anti-reflective film layer was transferred to the carbon layer without any problem.

The result of Example 1-11 shows that the etching progresses without any problem, even when argon is added as a dilution gas to the etching gas.

The results of Examples 1-12, 1-13 show that the pattern of the anti-reflective film layer was transferred to the carbon layer without any problem, even when the temperature of the etching test piece was set to 0° C., 60° C., respectively. Further, the ratio between the long diameter LD and the short diameter SD (LD/SD) and the ratio between the bowing part diameter DA and the bottom part diameter DB (DA/DB) of the opening part of the anti-reflective film tended to approach 1 with an increase in the temperature.

The results of Examples 1-14, 1-15 show that the pattern of the anti-reflective film layer was transferred to the carbon layer without any problem, even when the RF power was set to 200 W, 800 W. When the RF power was increased, the long diameter LD, the short diameter SD, the bowing part diameter DA, and the bottom part diameter DB of the opening part in the anti-reflective film layer all tended to increase in length.

The result of Example 1-16 shows that the pattern of the anti-reflective film layer was transferred to the carbon layer without any problem, even when the pressure was set to 5 Pa.

The results of Example 1-17, Example 1-18 show that the pattern of the anti-reflective film layer was transferred to the carbon layer without any problem, even when the flow rate ratio between the fluoro-dithiethane and the oxygen gas was changed.

In Comparative Examples 1-1 to 1-5, the unpurified fluoro-dithiethane was used, and therefore the ratio between the long diameter LD and the short diameter SD (LD/SD) of the opening part in the anti-reflective film layer was 1.15 or more and the ratio between the bowing part diameter DA and the bottom part diameter DB (DA/DB) was 1.6 or more. This result shows that, when the fluoro-dithiethane containing metal for the etching gas is used, the bowing occurs, deteriorating the processing shape of the carbon layer.

From the results of Comparative Examples 1-6, 1-7, the processing shape of the carbon layer deteriorated in the case where the pattern of the anti-reflective film layer was transferred to the carbon layer using the carbonyl sulfide as compared with the case where the gas containing the fluoro-dithiethane was used as the etching gas, regardless of the presence or absence of metals in the carbonyl sulfide. This result suggested that the improvement effect of the processing shape of the carbon layer by reducing the metal content is exhibited only in a specific sulfur compound.

In Comparative Example 1-8, the use of the etching gas not containing the fluoro-dithiethane deteriorated the processing shape of the carbon layer. This result shows that the use of the fluoro-dithiethane is effective in improving the processing shape of the carbon layer.

The result of Example 2-1 shows that the pattern of the anti-reflective film layer was transferred to the carbon layer without any problem, even when the etching was performed by the alternating process.

The result of Example 2-2 shows that the pattern of the anti-reflective film layer was transferred to the carbon layer without any problem, even when the etching gas used for the sidewall protection process did not contain an oxygen gas.

The result of Example 2-3 shows that the pattern of the anti-reflective film layer was transferred to the carbon layer without any problem, even when argon was contained in the etching gas.

The results of Examples 2-4, 2-5 show that the pattern of the anti-reflective film layer was transferred to the carbon layer without any problem, even when the temperature of the etching test piece was differentiated between the deep etching process and the sidewall protection process or even when the temperature of the etching test piece was set to 40° C. in both the deep etching process and the sidewall protection process.

The result of Comparative Example 2-1 shows that, when the fluoro-dithiethane containing metal for the etching gas is used, the bowing occurs, deteriorating the processing shape of the carbon layer.

The results of Examples 3-1 to 3-5, 3-15, 3-16 show that, when the etching gas containing the fluoro-dithiethane was used, the pattern of the anti-reflective film layer was transferred to the carbon layer without any problem even when the diameter of the through hole in the pattern formed in the anti-reflective film layer was 50 nm.

The results of Examples 3-6 to 3-14 show that the pattern of the anti-reflective film layer was transferred to the carbon layer without any problems, even when various etching conditions, such as the temperature and the RF power, of the etching test piece were variously changed.

In Comparative Examples 3-1 to 3-5, the unpurified fluoro-dithiethane was used, and therefore the ratio between the long diameter LD and the short diameter SD (LD/SD) of the opening part in the anti-reflective film layer was 1.19 or more and the ratio between the bowing part diameter DA and the bottom part diameter DB (DA/DB) was 1.6 or more. This result shows that, when the fluoro-dithiethane containing metal for the etching gas is used, the bowing occurs, deteriorating the processing shape of the carbon layer.

From the results of Comparative Examples 3-6, 3-7, the processing shape of the carbon layer deteriorated in the case where the pattern of the anti-reflective film layer was transferred to the carbon layer using the carbonyl sulfide as compared with the case where the gas containing the fluoro-dithiethane was used as the etching gas, regardless of the presence or absence of metals in the carbonyl sulfide. This result suggested that the improvement effect of the processing shape of the carbon layer by reducing the metal content is exhibited only in a specific sulfur compound.

In Comparative Example 3-8, the use of the etching gas not containing the fluoro-dithiethane deteriorated the processing shape of the carbon layer. This result shows that the use of the fluoro-dithiethane is effective in improving the processing shape of the carbon layer.

The results of Examples 4-1 to 4-6 show that, when the etching gas containing the fluoro-dithiethane was used, the pattern of the anti-reflective film layer was transferred to the carbon layer without any problem even when the diameter of the through hole in the pattern formed in the anti-reflective film layer was 50 nm.

The result of Comparative Example 4-1 shows that, when the fluoro-dithiethane containing metal for the etching gas is used, the bowing occurs, deteriorating the processing shape of the carbon layer.

The results of Examples 5-1 to 5-5, 5-19 show the following facts. More specifically, it is shown that, by the use of the mixed gas of the fluoro-dithiethane and an oxygen gas as the etching gas, the carbon layer directly under the opening part in the anti-reflective film layer was etched until the etch stop layer was exposed. At this time, the maximum width SW of the opening part of the linear through hole 103a in the anti-reflective film layer after the etching was 200 to 207 nm. The ratio between the bowing part width WA and the bottom part width WB (WA/WB) is 1.1 to 1.3, which shows that the pattern of the anti-reflective film layer was transferred to the carbon layer without any problem.

The results of Examples 5-6 to 5-10 show the following facts. More specifically, it is shown that, even when a nitrogen gas, the mixed gas of the nitrogen gas and an oxygen gas, the mixed gas of tetrafluoromethane and the oxygen gas, the mixed gas of octafluorocyclobutane and the oxygen gas, and tetrafluoromethane were used as the second etching compound, the etching progressed without any problem, and the pattern of the anti-reflective film layer was transferred to the carbon layer without any problem.

The result of Example 5-11 shows that the etching progresses without any problem, even when argon is added as a dilution gas to the etching gas.

The results of Examples 5-12, 5-13 show that the pattern of the anti-reflective film layer was transferred to the carbon layer without any problem, even when the temperature of the etching test piece was set to 0° C., 60° C., respectively. Further, the ratio between the bowing part width WA and the bottom part width WB (WA/WB) tended to approach 1 with an increase in the temperature.

The results of Examples 5-14, 5-15 show that the pattern of the anti-reflective film layer was transferred to the carbon layer without any problem, even when the RF power was set to 200 W, 800 W. When the RF power was increased, the maximum width SW, the bowing part width WA, and the bottom part width WB of the opening part of the linear through hole 103a in the anti-reflective film layer all tended to increase in length.

The result of Example 5-16 shows that the pattern of the anti-reflective film layer was transferred to the carbon layer without any problem, even when the pressure was set to 5 Pa.

The results of Example 5-17, Example 5-18 show that the pattern of the anti-reflective film layer was transferred to the carbon layer without any problem, even when the flow rate ratio between the fluoro-dithiethane and the oxygen gas was changed.

In Comparative Examples 5-1 to 5-5, the unpurified fluoro-dithiethane was used, and therefore the maximum width SW of the opening part of the linear through hole 103a in the anti-reflective film layer was 210 nm or more, and the ratio between the bowing part width WA and the bottom part width WB (WA/WB) was 1.4. This result shows that, when the fluoro-dithiethane containing metal for the etching gas is used, the bowing occurs, deteriorating the processing shape of the carbon layer.

From the results of Comparative Examples 5-6, 5-7, the processing shape of the carbon layer deteriorated in the case where the pattern of the anti-reflective film layer was transferred to the carbon layer using the carbonyl sulfide as compared with the case where the gas containing the fluoro-dithiethane was used as the etching gas, regardless of the presence or absence of metals in the carbonyl sulfide. This result suggested that the improvement effect of the processing shape of the carbon layer by reducing the metal content is exhibited only in a specific sulfur compound.

In Comparative Example 5-8, the use of the etching gas not containing the fluoro-dithiethane deteriorated the processing shape of the carbon layer. This result shows that the use of the fluoro-dithiethane is effective in improving the processing shape of the carbon layer.

The result of Example 6-1 shows that the pattern of the anti-reflective film layer was transferred to the carbon layer without any problem, even when the etching was performed by the alternating process.

The result of Example 6-2 shows that the pattern of the anti-reflective film layer was transferred to the carbon layer without any problem, even when the etching gas used for the sidewall protection process did not contain an oxygen gas.

The result of Example 6-3 shows that the pattern of the anti-reflective film layer was transferred to the carbon layer without any problem, even when argon was contained in the etching gas.

The results of Examples 6-4, 6-5 show that the pattern of the anti-reflective film layer was transferred to the carbon layer without any problem, even when the temperature of the etching test piece was differentiated between the deep etching process and the sidewall protection process or even when the temperature of the etching test piece was set to 40° C. in both the deep etching process and the sidewall protection process.

The result of Comparative Example 6-1 shows that, when the fluoro-dithiethane containing metal for the etching gas is used, the bowing occurs, deteriorating the processing shape of the carbon layer.

### REFERENCE SIGNS LIST

100 silicon substrate
102 carbon layer
103 anti-reflective film layer
103a through hole
105 hole
105a side wall surface
200 etching device
210 chamber
220 upper electrode
221 lower electrode
300 fluoro-dithietane gas supply section
310 inert gas supply section
320 second etching compound gas supply section
400 member to be etched

1. An etching method comprising:
an etching step of bringing an etching gas containing an etching compound into contact with a member to be etched having an etching object subject to etching by the etching gas, plasm etching the etching object, and forming a hole in the etching object, wherein
the etching object has a carbon material,
the etching compound is fluoro-dithiethane represented by Chemical Formula CₓF_{y}S₂, wherein, in Chemical Formula above, x is 2 or more and 6 or less and y is 4 or more and 12 or less, and
the etching gas contains or does not contain at least one type of metal among sodium, magnesium, aluminum, potassium, calcium, chromium, manganese, iron, cobalt, nickel, copper, and molybdenum, and, when the at least one type of metal is contained, a total concentration of all types of the contained metals is 100 ppb by mass or less.

2. The etching method according to claim 1, wherein the fluoro-dithiethane has at least one type among 2,2,4,4-tetrafluoro-1,3-dithietane, 1,1,2,2,3,3,4,4-octafluoro-1,3-dithietane, 2,2,4-trifluoro-4-trifluoromethyl-1,3-dithietane, 2,4-difluoro-2,4-bis(trifluoromethyl)-1,3-dithietane, and 2,2,4,4-tetrakis(trifluoromethyl)-1,3-dithietane.

3. The etching method according to claim 1, wherein the carbon material has at least one of amorphous carbon and carbon-doped silicon oxide.

4. The etching method according to claim 1, wherein the etching gas contains the fluoro-dithiethane and at least one of a second etching compound and an inert gas.

5. The etching method according to claim 4, wherein the second etching compound is at least one type among oxygen gas, nitrogen gas, and fluorocarbon.

6. The etching method according to claim 1, wherein a temperature condition of the etching step is 0° C. or more and 40° C. or less.

7. The etching method according to claim 1, wherein a pressure condition of the etching step is 1 Pa or more and 5 Pa or less.

8. The etching method according to claim 2, wherein the carbon material has at least one of amorphous carbon and carbon-doped silicon oxide.

9. The etching method according to claim 2, wherein the etching gas contains the fluoro-dithiethane and at least one of a second etching compound and an inert gas.

10. The etching method according to claim 9, wherein the second etching compound is at least one type among oxygen gas, nitrogen gas, and fluorocarbon.

11. The etching method according to claim 2, wherein a temperature condition of the etching step is 0° C. or more and 40° C. or less.

12. The etching method according to claim 2, wherein a pressure condition of the etching step is 1 Pa or more and 5 Pa or less.
